(19) United States
(12) Patent Application Publication
(10) Pub. No.: US 2026/0059799 A1
(43) Pub. Date: Feb. 26, 2026

(54) INTEGRATED CIRCUIT DEVICE AND MANUFACTURING METHOD THEREOF

(71) Applicants: TAIWAN SEMICONDUCTOR MANUFACTURING COMPANY, LTD., Hsinchu (TW); NATIONAL TAIWAN UNIVERSITY, Taipei (TW)

(72) Inventors: Jih-Chao CHIU, New Taipei City (TW); Yu-Shan WU, New Taipei City (TW); Yuan-Ming LIU, Taichung City (TW); Chee-Wee LIU, Taipei City (TW)

(73) Assignees: TAIWAN SEMICONDUCTOR MANUFACTURING COMPANY, LTD., Hsinchu (TW); NATIONAL TAIWAN UNIVERSITY, Taipei (TW)

(21) Appl. No.: 18/814,224

(22) Filed: Aug. 23, 2024

(51) Int. Cl. H01L 29/786; H01L 21/8234; H01L 27/12; H01L 29/06; H01L 29/10; H01L 29/161; H01L 29/22; H01L 29/24; H01L 29/423; H01L 29/66; H01L 29/775; H10B 12/00

(52) U.S. Cl. CPC H10D 30/6734; H10D 30/014; H10D 30/023; H10D 30/43; H10D 30/6735; H10D 30/6757; H10D 62/121; H10D 62/292; H10D 64/015; H10D 84/0128; H10D 84/0142; H10D 84/038; H10D 86/481; H10D 86/60; H10B 12/05; H10B 12/31; H10D 1/714; H10D 1/716; H10D 62/832; H10D 62/86; H10D 62/871

(57) ABSTRACT

A method for manufacturing an integrated circuit device is provided. The method includes depositing a dielectric layer over a substrate; depositing a first gate electrode layer over the dielectric layer; removing a first portion of the dielectric layer to leave an opening between the first gate electrode layer, the substrate, and second portions of the dielectric layer; depositing a first gate dielectric layer, such that the first gate dielectric layer has a first portion in the opening and a second portion over a top surface of the first gate electrode layer; and depositing a semiconductor layer, such that the semiconductor layer has a first portion in the opening and a second portion over a top surface of the first gate dielectric layer.

### BACKGROUND

The semiconductor industry has experienced rapid growth due to continuous improvements in the integration density of various electronic components (i.e., transistors, diodes, resistors, capacitors, etc.). For the most part, this improvement in integration density has come from repeated reductions in minimum feature size, which allows more components to be integrated into a given area.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-10B illustrate a method for manufacturing an integrated circuit device at various stages in accordance with some embodiments.

FIGS. 11-13B illustrate a method for manufacturing an integrated circuit device at various stages in accordance with some embodiments.

FIGS. 14-18C illustrate a method for manufacturing an integrated circuit device at various stages in accordance with some embodiments.

FIGS. 19-23B illustrate a method for manufacturing an integrated circuit device at various stages in accordance with some embodiments.

FIG. 23C is a circuit diagram of an integrated circuit device in accordance with some embodiments.

FIG. 24A is a cross-sectional view of an integrated circuit device in accordance with some embodiments.

FIG. 24B is a cross-sectional view taken along line B-B′ of FIG. 24A.

FIG. 24C is a circuit diagram of the integrated circuit device of FIG. 24A.

FIG. 25 is a voltage to current diagram of an integrated circuit device in accordance with some embodiments.

FIGS. 26-30B illustrate a method for manufacturing an integrated circuit device at various stages in accordance with some embodiments.

FIGS. 31-34B illustrate a method for manufacturing an integrated circuit device at various stages in accordance with some embodiments.

FIG. 34C is a circuit diagram of the integrated circuit device of FIG. 24A.

FIGS. 35-37 illustrate a method for manufacturing an integrated circuit device at various stages in accordance with some embodiments.

FIGS. 38-42B illustrate a method for manufacturing an integrated circuit device at various stages in accordance with some embodiments.

FIG. 43A is a schematic top view of an integrated circuit device in accordance with some embodiments.

FIG. 43B is a schematic cross-sectional view taken along line B-B of FIG. 43A.

FIG. 43C is a schematic cross-sectional view taken along line C-C of FIG. 43A.

FIG. 43D is a schematic cross-sectional view taken along line D-D of FIG. 43A.

FIGS. 44A-56C illustrate a method for manufacturing an integrated circuit device at various stages in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The gate all around (GAA) transistor structures may be patterned by any suitable method. For example, the structures may be patterned using one or more photolithography processes, including g double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in some embodiments, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

The term “multi-gate device” is used to describe a device (e.g., a semiconductor transistor) that has at least some gate material disposed on multiple sides of at least one channel of the device. In some examples, the multi-gate device may be referred to as a GAA device or a nanosheet device having gate material disposed on at least four sides of at least one channel of the device. The channel region may be referred to as a “nanowire,” which as used herein includes channel regions of various geometries (e.g., cylindrical, bar-shaped) and various dimensions. In some examples, the multi-gate device may be referred to as a FinFET device. However, one of ordinary skill would recognize that the teaching can apply to a single channel (e.g., single nanosheet) or any number of channels. One of ordinary skill may recognize other examples of semiconductor devices that may benefit from aspects of the present disclosure.

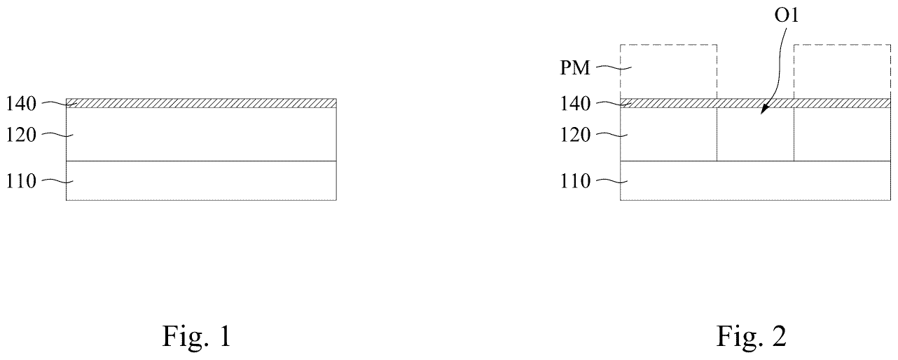

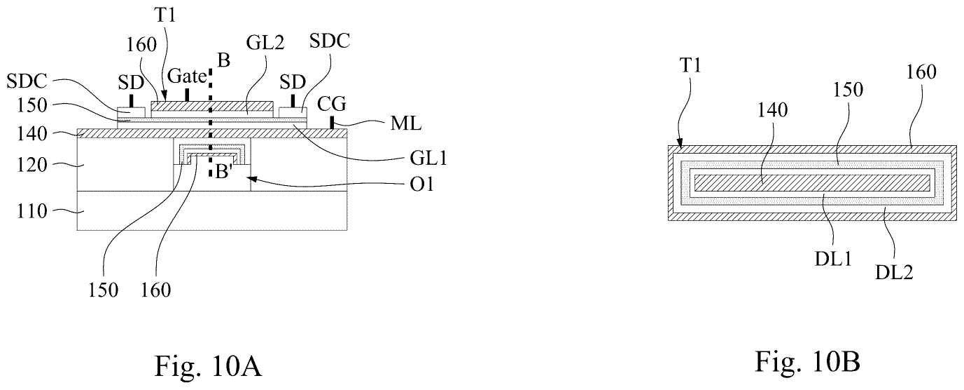

FIGS. 1-10B illustrate a method for manufacturing an integrated circuit device at various stages in accordance with some embodiments. FIGS. 1-10A are cross-sectional views of the integrated circuit device at various manufacturing stages in accordance with some embodiments. FIG. 10B is a cross-sectional view of the integrated circuit device taken along line B-B′ of FIG. 10A. It is understood that additional steps may be provided before, during, and after the steps shown in FIGS. 1-10B, and some of the steps described below can be replaced or eliminated for additional embodiments of the method. The order of the operations/processes may be interchangeable.

Reference is made to FIG. 1. A substrate 110 is provided. In some embodiments, the substrate 110 may include silicon (Si). Alternatively, the substrate 110 may include germanium (Ge), silicon germanium (SiGe), a III-V material (e.g., GaAs, GaP, GaAsP, AlInAs, AlGaAs, GaInAs, InAs, GalnP, InP, InSb, and/or GaInAsP; or a combination thereof) or other appropriate semiconductor materials. The substrate 110 may include Si, Ge, SiGe, a III-V material (e.g., GaAs, GaP, GaAsP, AlInAs, AlGaAs, GaInAs, InAs, GaInP, InP, InSb, and/or GaInAsP; or a combination thereof) or other appropriate semiconductor materials. Also, the substrate 110 may include a buried dielectric layer such as a buried oxide (BOX) layer, such as that formed by a method referred to as separation by implantation of oxygen (SIMOX) technology, wafer bonding, selective epitaxial growth (SEG), or another appropriate method. The substrate 110 may include a glass material.

A dielectric layer 120 is deposited over a substrate 110. In some embodiments, the dielectric layer 120 may include suitable dielectric material, such as silicon oxide, silicon nitride, other low-k dielectric, the like, or the combination thereof. The dielectric layer 120 may be referred to as a sacrificial layer in some embodiments.

A center gate electrode layer 140 is deposited over the dielectric layer 120. In some embodiments, the center gate electrode layer 140 may exemplarily include, but are not limited to, tungsten, aluminum, copper, nickel, cobalt, titanium, tantalum, titanium nitride, tantalum nitride, nickel silicide, cobalt silicide, platinum, TaC, TaSIN, TaCN, TiAl, TiAIN, or other suitable materials.

Reference is made to FIG. 2. A selective etching process is performed to remove a portion of the dielectric layer 120, thereby leaving an opening O1 among a bottom surface of the center gate electrode layer 140, the dielectric layer 120, and a top surface of the substrate 110. This step is also referred to as a metal release process. The selective etching process may use etchants, such as buffer oxide etchants (BOE) (e.g., HE), such that the selective etching process removes the dielectric layer 120 at a faster etch rate than removes the substrate 110 and the center gate electrode layer 140.

In some embodiments, prior to the selective etching process, a patterned mask PM is formed over the dielectric layer 120, for example, by a photolithography process. The photolithography process may include photoresist coating (e.g., spin-on coating), soft baking, mask aligning, exposure, post-exposure baking, developing the photoresist, rinsing, drying (e.g., hard baking), and/or other applicable processes. In some embodiments, the patterned mask PM may include a photoresist layer, a hard mask layer (e.g., silicon nitride layer), or the combination thereof. The patterned mask PM may cover a first portion of the dielectric layer 120 and expose a second portion of the dielectric layer 120. Through the patterned mask PM, the selective etching process may remove the second portion of the dielectric layer 120 exposed by the patterned mask PM, and the first portion of the dielectric layer 120 covered by the patterned mask PM is protected from being etched. After the selective etching process, the patterned mask PM can be removed by suitable removal process.

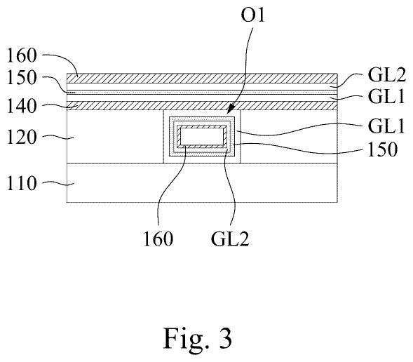

Reference is made to FIG. 3. A gate dielectric layer GL1, a semiconductor layer 150, a gate dielectric layer GL2, and a gate electrode layer 160 are deposited over a top surface of the center gate electrode layer 140 and into the opening O1 in a sequence. The gate dielectric layer GL1 is deposited over the center gate electrode layer 140. The gate dielectric layer GL1 may include suitable dielectric/insulating material, such as silicon nitride, silicon oxide, the like, or the combination thereof. In some embodiments, the gate dielectric layer GL1 may include high-k dielectric materials such as hafnium oxide (HfO₂), hafnium silicon oxide (HfSiO), hafnium silicon oxynitride (HfSiON), hafnium tantalum oxide (HfTaO), hafnium titanium oxide (HfTiO), hafnium zirconium oxide (HfZrO; HZO), lanthanum oxide (LaO), zirconium oxide (ZrO₂), titanium oxide (TiO₂), tantalum oxide (Ta₂O₅), yttrium oxide (Y₂O₃), strontium titanium oxide (SrTiO₃, STO), barium titanium oxide (BaTiO₃, BTO), barium zirconium oxide (BaZrO), hafnium lanthanum oxide (HfLaO), lanthanum silicon oxide (LaSiO), aluminum silicon oxide (AlSiO), aluminum oxide (Al₂O₃), the like, or combinations thereof. The gate dielectric layer GL1 may be deposited by atomic layer deposition (ALD) process.

The semiconductor layer 150 is deposited over the dielectric layer GL1. The semiconductor layer 150 may be referred to as a metal-oxide semiconductor layer. In some embodiments, metal-oxide semiconductors contain a metal cation (i.e., Zn, Sn, In, Cu, and Ni) and an oxide anion, including binary metal oxides (e.g., In₂O₃, ZnO), ternary metal oxides (e.g., InZnO(IZO), InSnO), and quaternary metal oxides (e.g., InGaZnO(IGZO)), the like, or the combination thereof. In the present embodiments, the semiconductor layer 150 may have a fermi level that sits close to the conduction band, and therefore these materials are naturally n-type, and capable of serving as a n-type channel layer for an n-type device. In some alternative embodiments, the semiconductor layer 150 may be naturally p-type, such as a GeSn layer. The semiconductor layer 150 may include IGZO, GeSn, Si, Ge, SiGe, or other suitable channel material. The semiconductor layer 150 is deposited by atomic layer deposition (ALD), sputter, the like, or the combination thereof.

The gate dielectric layer GL2 is deposited over the semiconductor layer 150. The gate dielectric layer GL2 may include materials as mentioned along with the gate dielectric layer GL1. The gate dielectric layer GL2 may be deposited by atomic layer deposition (ALD) process.

The gate electrode layer 160 is deposited over the gate dielectric layer GL2. In some embodiments, the gate electrode layer 160 may exemplarily include, but are not limited to, tungsten, aluminum, copper, nickel, cobalt, titanium, tantalum, titanium nitride, tantalum nitride, nickel silicide, cobalt silicide, TaC, TaSIN, TaCN, TiAl, TiAIN, or other suitable materials.

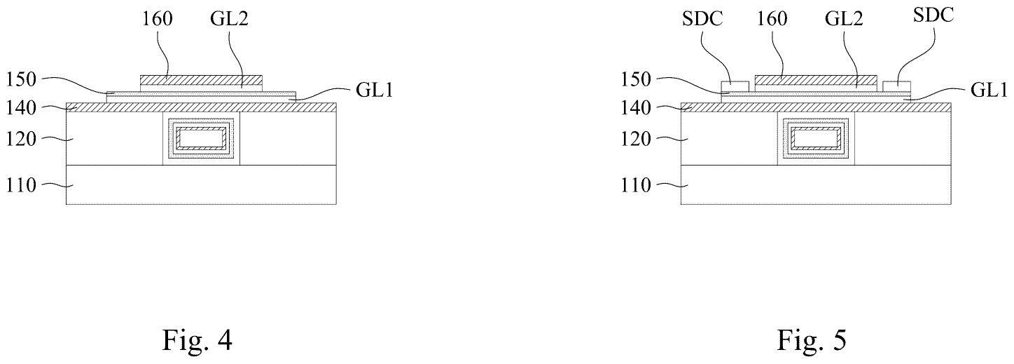

Reference is made to FIG. 4. A step patterning process is performed such that the widths of the center gate electrode layer 140, the semiconductor layer 150, and the gate electrode layer 160 decrease in a sequence from bottom to top. After the step patterning process, portions of the semiconductor layer 150 are exposed by the gate electrode layer 160, and portions of the center gate electrode layer 140 are exposed by the semiconductor layer 150. In some embodiments, the step patterning process may include the formation of a photoresist mask and plural cycles, each cycle includes a photoresist trimming process and an etching process and followed by the etching process. In some alternative embodiments, the step patterning process may include plural cycles, each cycle includes the formation of a photoresist mask and an etching process followed by the formation of the photoresist mask.

Reference is made to FIG. 5. Source/drain contacts SDC are formed on the exposed portions of the semiconductor layer 150. The source/drain contacts SDC may include suitable metals, such as TIN, Ti, W, Al, Cu, Ru, Ni, Co, alloys of these, combinations thereof, and the like. The source/drain contacts SDC may make physical and electrical connections to the semiconductor layer 150. The source/drain contacts SDC may be referred to as source/drain electrodes in some embodiments.

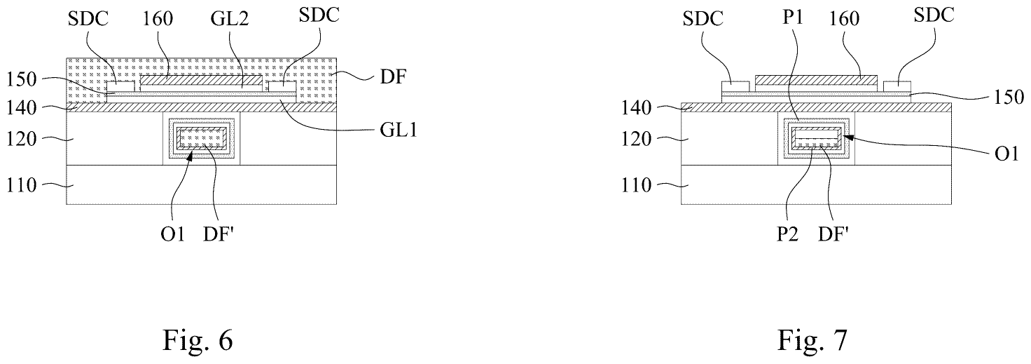

Reference is made to FIG. 6. A dielectric filling layer DF is deposited over the structure of FIG. 5 and filling the opening O1. The dielectric filling layer DF may include suitable dielectric/insulating material, such as silicon nitride, silicon oxide, other low-k dielectrics, the like, or the combination thereof.

Reference is made to FIG. 7. An etching back process is performed to remove a portion of the dielectric filling layer DF over the center gate electrode layer 140 and remove a portion of the dielectric filling layer DF in the opening O1. After the etching back process, the dielectric filling layer DF (referring to FIG. 6) may have a residue portion remaining in the opening O1. The residue portion of the dielectric filling layer DF (referring to FIG. 6) may be referred to as dielectric residue DF′. Through the configuration, a first portion P1 of the layers 150, 160, GL1, and GL2 in the opening O1 is exposed by the dielectric residue DF′, and a second portion P2 of the layers 150, 160, GL1, and GL2 in the opening O1 is covered by the dielectric residue DF′.

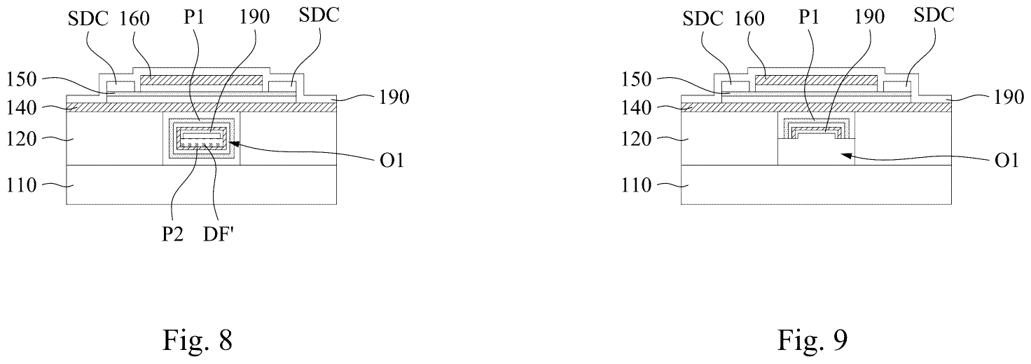

Reference is made to FIG. 8. A protection layer 190 is conformally deposited over the structure of FIG. 7. The protection layer 190 extend over top surfaces of the center gate electrode layer 140, the semiconductor layer 150, and the gate electrode layer 160. The protection layer 190 may include polymer or metals (e.g., TiN, W, Al, etc.). The protection layer 190 may be deposited by ALD process. With the presence of the dielectric residue DF′, the first portion P1 of the layers 150, 160, GL1, and GL2 in the opening O1 exposed by the dielectric residue DF′ may be coated with the protection layer 190. And, the second portion P2 of the layers 150, 160, GL1, and GL2 in the opening O1 covered by the dielectric residue DF′ is spaced apart from and uncovered by the protection layer 190 by the dielectric residue DF′.

Reference is made to FIG. 9. The dielectric residue DF′ and the second portion P2 of the layers 150, 160, GL1, and GL2 (referring to FIG. 8) in the opening O1 are removed. The removal may include a suitable etching process, such as a dry etching process, a wet etching process, or the combination thereof. The etching process may remove the dielectric residue DF′ and the underlying materials (e.g., the layers 150, 160, GL1, and GL2) at a faster rate than it removes the protection layer 190, such that the first portion P1 of the layers 150, 160, GL1, and GL2 in the opening O1 covered by the protection layer 190 are protected from being etched by the protection layer 190. After the removal, the substrate 110 is exposed by the opening O1. And, the first portion P1 of the layers 150, 160, GL1, and GL2 is spaced apart from the substrate 110.

Reference is made to FIGS. 10A and 10B. The protection layer 190 is removed by suitable cleaning/etching process. As shown in FIG. 10B, the semiconductor layer 150 surrounds the center gate electrode layer 140, and the gate electrode layer 160 surrounds the semiconductor layer 150. Through the configuration, a gate/channel-all-around transistor T1 is formed.

Plural metal interconnects ML are formed. Through the metal interconnects ML, the center gate line CG, the source/drain lines SD, and the gate line Gate, are connected to the center gate electrode layer 140, two ends of the semiconductor layer 150, the gate electrode layer 160 of the transistor T1, respectively. The integrated gate/channel-all-around structure greatly increases the effective channel width (W_{eff}) and the current. And, the center gate can also act as body electrode to modulate the threshold voltage of the transistor.

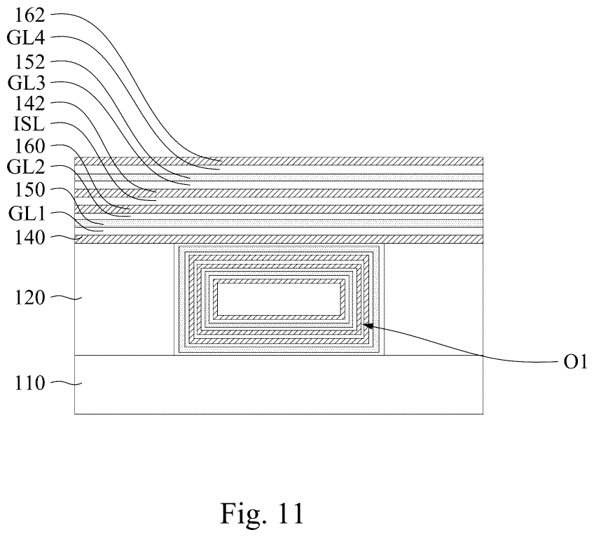

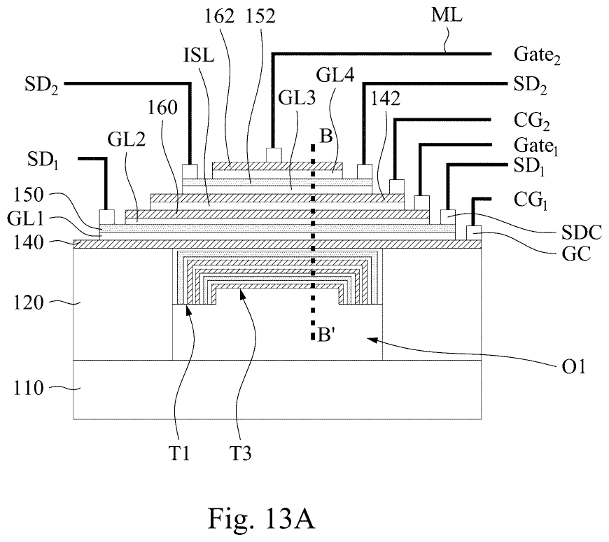

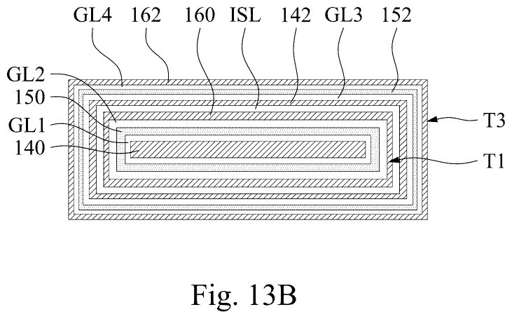

FIGS. 11-13B illustrate a method for manufacturing an integrated circuit device at various stages in accordance with some embodiments. FIGS. 11-13A are cross-sectional views of the integrated circuit device at various manufacturing stages in accordance with some embodiments. FIG. 13B is a cross-sectional view of the integrated circuit device taken along line B-B′ of FIG. 13A. Detail of the present embodiments are similar to that of FIGS. 1-10B, except that two semiconductor layers are used in the present embodiments. It is understood that additional steps may be provided before, during, and after the steps shown in FIGS. 1-13B, and some of the steps described below can be replaced or eliminated for additional embodiments of the method. The order of the operations/processes may be interchangeable.

Reference is made to FIG. 11. After the metal release process as shown in FIGS. 1 and 2, an opening O1 is formed among a bottom surface of the center gate electrode layer 140, the dielectric layer 120, and a top surface of the substrate 110. Subsequently, the gate dielectric layer GL1, the semiconductor layer 150, the gate dielectric layer GL2, the gate electrode layer 160, the dielectric isolation layer ISL, a gate electrode layer 142, a gate dielectric layer GL3, the semiconductor layer 152, the gate dielectric layer GL4, and the gate electrode layer 162 are deposited over a top surface of the center gate electrode layer 140 and into the opening O1 in a sequence. The gate dielectric layers GL3 and GL4 may include materials as mentioned along with the gate dielectric layer GL1. The gate dielectric layers GL3 and GL4 may be deposited by ALD process. The semiconductor layer 152 may include materials as mentioned along with the semiconductor layer 150. The gate electrode layers 142 and 162 may include materials as mentioned along with the center gate electrode layer 140 and the gate electrode layer 160.

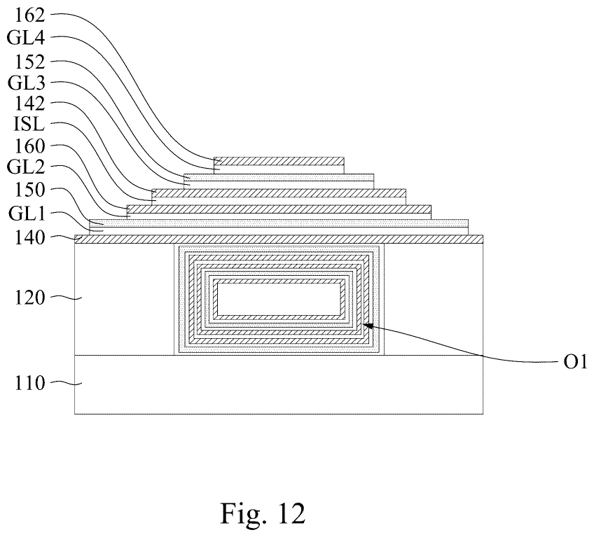

Reference is made to FIG. 12. A step patterning process is performed such that the widths of the center gate electrode layer 140, the semiconductor layer 150, the gate electrode layer 160, the gate electrode layer 142, the semiconductor layer 152, and the gate electrode layer 162 decrease in a sequence from bottom to top. As aforementioned, the step patterning process may include the formation of a photoresist mask and plural cycles, each cycle includes a photoresist trimming process and an etching process and followed by the etching process. After the step patterning process, each of the layers 140, 150, 160, 142, 152, 162 has portions exposed by the next layer thereon.

Reference is made to FIGS. 13A and 13B. Source/drain contacts SDC are formed on the exposed portions of the semiconductor layer 150 and the semiconductor layer 152. And, gate contacts GC are formed on the exposed portions of the center gate electrode layer 140, the gate electrode layer 160, the gate electrode layer 142, and the gate electrode layer 162. The source/drain contacts SDC and the gate contacts GC may include suitable metals, such as TIN, Ti, W, Al, Cu, Ru, Ni, Co, alloys of these, combinations thereof, and the like. The source/drain contacts SDC may make physical and electrical connections to the semiconductor layer 150, and the gate contacts GC may make physical and electrical connections to the center gate electrode layer 140, the gate electrode layer 160, the gate electrode layer 142, and the gate electrode layer 162. Through the configuration, a channel-all-around transistor is formed. A transistor stacking technique is achieved, and all gates and source/drain nodes can be controlled separately. For example, the dielectric isolation layer ISL spaces the outer transistor T3 from the inner transistor T1. The inner transistor T1 includes the center gate electrode layer 140, the semiconductor layer 150, the gate electrode layer 160. The outer transistor T3 includes the gate electrode layer 142, the semiconductor layer 152, and the gate electrode layer 162, respectively.

Plural metal interconnects ML are formed. Through the metal interconnects ML, the center gate line CG₁, the source/drain lines SD₁, and the gate line Gate₁, are connected to the center gate electrode layer 140, two ends of the semiconductor layer 150, the gate electrode layer 160 of the inner transistor, respectively. And, the gate line CG₂, the source/drain line SD₂, and the gate line Gate₂, are connected to the gate electrode layer 142, the semiconductor layer 152, and the gate electrode layer 162, respectively. The integrated circuit device of FIGS. 13A and 13B, can be directed to two-transistor and zero-capacitor (2TOC) dynamic random-access memory (DRAM) cell.

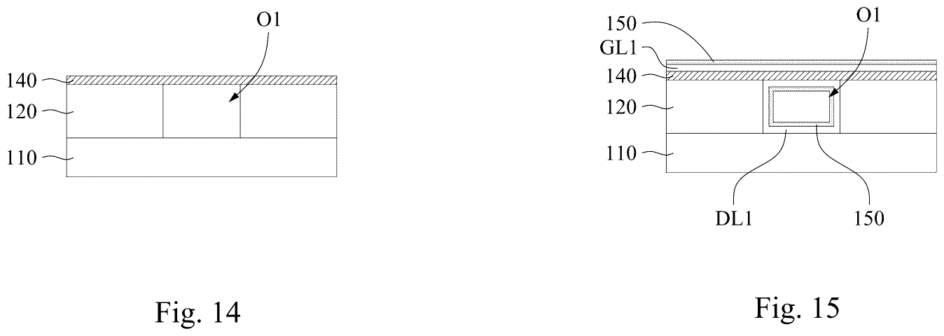

FIGS. 14-18C illustrate a method for manufacturing an integrated circuit device at various stages in accordance with some embodiments. Detail of the present embodiments are similar to that of FIGS. 1-10B, except that the gate electrode layer 160 (referring to FIGS. 1-10B) is omitted in the present embodiments. It is understood that additional steps may be provided before, during, and after the steps shown in FIGS. 14-18C, and some of the steps described below can be replaced or eliminated for additional embodiments of the method. The order of the operations/processes may be interchangeable.

Reference is made to FIG. 14. After the metal release process as shown in FIGS. 1 and 2, an opening O1 is formed among a bottom surface of the center gate electrode layer 140, the dielectric layer 120, and a top surface of the substrate 110.

Reference is made to FIG. 15. A gate dielectric layer GL1 and a semiconductor layer 150 are deposited over a top surface of the center gate electrode layer 140 and into the opening O1 in a sequence.

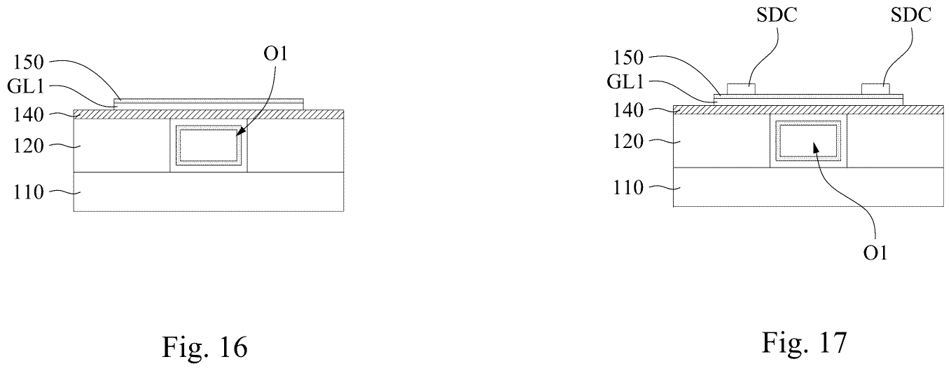

Reference is made to FIG. 16. A patterning process is performed to remove the portions of the gate dielectric layer GL1 and the semiconductor layer 150 to expose the portions of the center gate electrode layer 140.

Reference is made to FIG. 17. Source/drain contacts SDC are formed on the top surface of the semiconductor layer 150. The source/drain contacts SDC may include suitable metals, such as TIN, Ti, W, Al, Cu, Ru, Ni, Co, alloys of these, combinations thereof, and the like. The source/drain contacts SDC may make physical and electrical connections to the semiconductor layer 150.

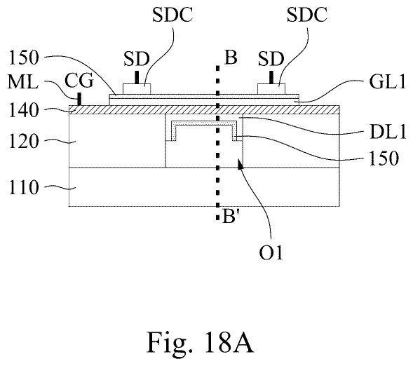

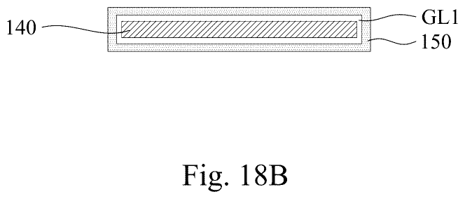

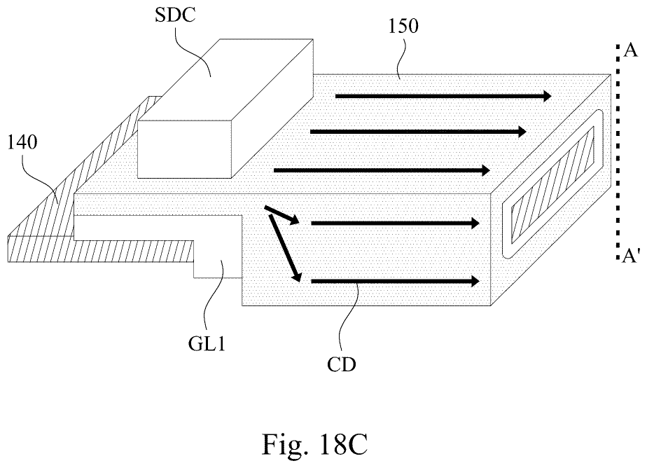

Reference is made to FIGS. 18A-18B. By depositing a dielectric filling layer over the structure of FIG. 17 (as the step shown in FIG. 6), etching back the dielectric filling layer into the dielectric residue (as the step shown in FIG. 7), conformally depositing a protection layer (as the step shown in FIG. 8), and removing the dielectric residue (as the step shown in FIG. 9). Lower portions of the gate dielectric layer GL1 and the semiconductor layer 150 are etched away from the substrate 110. The semiconductor layer 150 may surround the gate dielectric layer GL1 and the center gate electrode layer 140 and spaced apart from the substrate 110.

Plural metal interconnects ML are formed. Through the metal interconnects ML, the center gate line CG and the source/drain lines SD are connected to the center gate electrode layer 140 and two ends of the semiconductor layer 150, respectively. The integrated channel-all-around structure greatly increases the effective channel width (W_{eff}) and the current.

FIG. 18C shows a schematic view of the center gate electrode layer 140 and the semiconductor layer 150. Arrows CD indicates directions of device current. In the present embodiments, by using the semiconductor layer 150 surrounding the center gate electrode layer 140, the current may flow through a portion of the semiconductor layer 150 over a top surface of the center gate electrode layer 140 and a portion of the semiconductor layer 150 on a sidewall of the center gate electrode layer 140. Through the configuration, the device current can be increased.

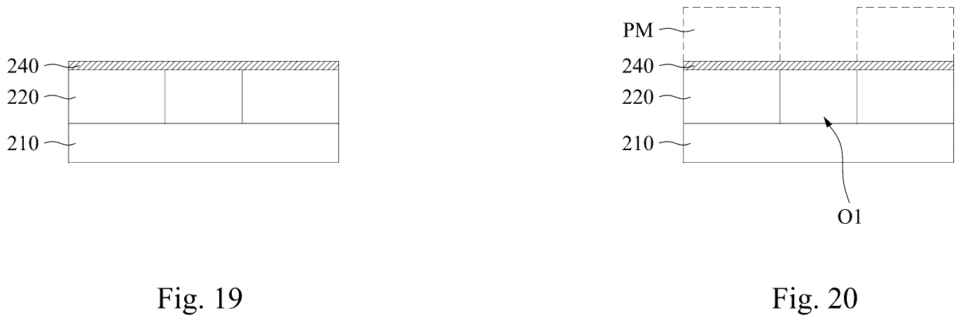

FIGS. 19-23B illustrate a method for manufacturing an integrated circuit device at various stages in accordance with some embodiments. Details of the present embodiments are similar to those illustrated in FIGS. 1-10B, except that the integrated circuit device includes a center semiconductor layer 240 and a MIM capacitor C1 surrounding the center semiconductor layer 240. It is understood that additional steps may be provided before, during, and after the steps shown in FIGS. 19-23B, and some of the steps described below can be replaced or eliminated for additional embodiments of the method. The order of the operations/processes may be interchangeable.

Reference is made to FIG. 19. A dielectric layer 220 is deposited over a substrate 210. In some embodiments, the dielectric layer 220 may include suitable dielectric/insulating material (e.g., silicon nitride, silicon oxide, other low-k dielectric), suitable semiconductor material (e.g., Si, SiGe, Ge), the like, or the combination thereof. The dielectric layer 220 may be referred to as a sacrificial layer in some embodiments.

A semiconductor layer 240 is deposited over the dielectric layer 220. The semiconductor layer 240 may be referred to as a metal-oxide semiconductor layer. In some embodiments, metal-oxide semiconductors contain a metal cation (i.e., Zn, Sn, In, Cu, and Ni) and an oxide anion, including binary metal oxides (e.g., In₂O₃, ZnO), ternary metal oxides (e.g., InZnO(IZO), InSnO), and quaternary metal oxides (e.g., InGaZnO(IGZO)), the like, or the combination thereof. The material of the semiconductor layer 240 may be different from that of the dielectric layer 220. In the present embodiments, the semiconductor layer 240 may have a fermi level that sits close to the conduction band, and therefore these materials are naturally n-type, and capable of serving as a n-type channel layer for an n-type device. In some alternative embodiments, the semiconductor layer 240 may be naturally p-type, such as a GeSn or SiGe layer. The semiconductor layer 240 is deposited by atomic layer deposition (ALD), sputter, the like, or the combination thereof.

Reference is made to FIG. 20. A selective etching process is performed to remove a portion of the dielectric layer 220, thereby leaving an opening O1 among a bottom surface of the semiconductor layer 240, the dielectric layer 220, and a top surface of the substrate 210. This step is also referred to as a channel release process. The selective etching process may use etchants, such as buffer oxide etchants (BOE) (e.g., HE), such that the selective etching process removes the dielectric layer 220 (referring to FIG. 19) at a faster etch rate than removes the underlying materials (e.g., the substrate 210).

In some embodiments, prior to the selective etching process, a patterned mask PM is formed over the dielectric layer 220, for example, by a photolithography process. The photolithography process may include photoresist coating (e.g., spin-on coating), soft baking, mask aligning, exposure, post-exposure baking, developing the photoresist, rinsing, drying (e.g., hard baking), and/or other applicable processes. In some embodiments, the patterned mask PM may include a photoresist layer, a hard mask layer (e.g., silicon nitride layer), or the combination thereof. The patterned mask PM may cover a first portion of the dielectric layer 220 and expose a second portion of the dielectric layer 220. Through the patterned mask PM, the selective etching process may remove the second portion of the dielectric layer 220 exposed by the patterned mask PM, and the first portion of the dielectric layer 220 covered by the patterned mask PM is protected from being etched. After the selective etching process, the patterned mask PM may be removed by suitable removal process.

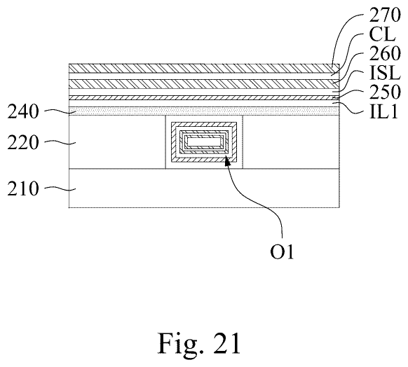

Reference is made to FIG. 21. A gate dielectric layer IL1, a gate electrode layer 250, a dielectric isolation layer ISL, a capacitor electrode layer 260, a capacitor dielectric layer CL, and a capacitor electrode layer 270 are deposited in a sequence over a top surface of the semiconductor layer 240 and into the opening O1. The dielectric isolation layer ISL may include silicon oxide, other low-k dielectric materials, the like, or the combination thereof. The capacitor dielectric layer CL may include a high-k dielectric material, such as Al₂O₃, HfO₂, TiO₂, ZrO₂, etc. The gate electrode layer 250, the capacitor electrode layer 260, and the capacitor electrode layer 270 may include suitable metals, such as TiN, Al, Ti, etc.

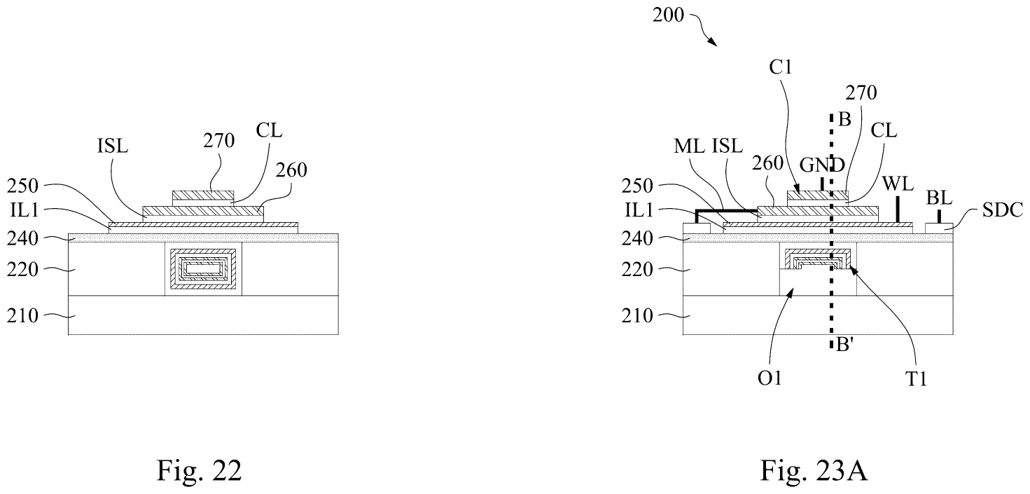

Reference is made to FIG. 22. A step patterning process is performed such that the widths of the gate electrode layer 250, the capacitor electrode layer 260, and the capacitor electrode layer 270 decrease in a sequence from bottom to top. As aforementioned, the step patterning process may include the formation of a photoresist mask and plural cycles, each cycle includes a photoresist trimming process and an etching process and followed by the etching process. After the step patterning process, portions of the semiconductor layer 240 are exposed by the gate electrode layer 250, portions of the gate electrode layer 250 are exposed by the capacitor electrode layer 260, and portions of the capacitor electrode layer 260 are exposed by the capacitor electrode layer 270.

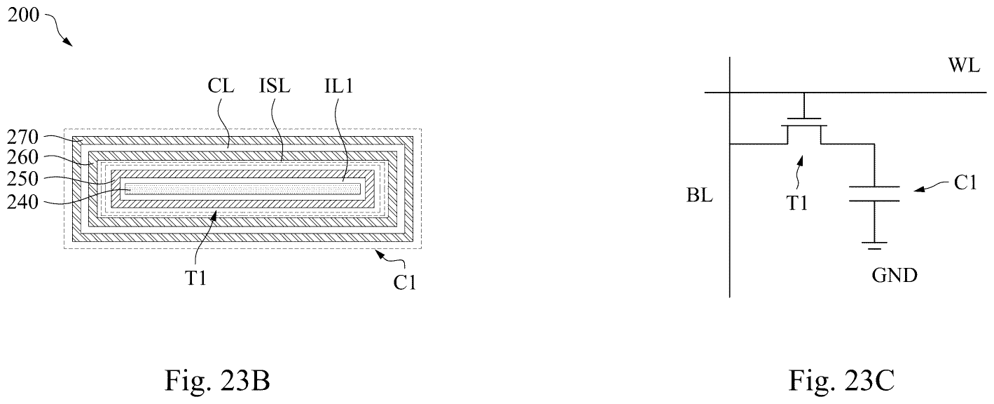

Reference is made to FIG. 23A. Source/drain contacts SDC are formed on the exposed portions of the semiconductor layer 240. The source/drain contacts SDC may include suitable metals, such as TIN, Ti, W, Al, Cu, Ru, Ni, Co, alloys of these, combinations thereof, and the like. The source/drain contacts SDC may make physical and electrical connections to the semiconductor layer 240. And, plural metal interconnects ML are formed. Through the metal interconnects ML, the word line WL, the bit line BL, and the ground potential GND are connected to the gate electrode layer 250, the semiconductor layer 240, and the capacitor electrode layer 270, respectively. And, one of the metal interconnects ML is formed to connect the source/drain contact SDC to the capacitor electrode layer 260.

FIG. 23B is a cross-sectional view taken along line B-B′ of FIG. 23A. The capacitor electrode layer 260, the capacitor dielectric layer CL, and the capacitor electrode layer 270 may form a capacitor C1. The gate electrode layer 250, the gate dielectric layer IL1, and the semiconductor layer 240 may form a gate-all-around transistor T2. The capacitor C1 surrounds the gate-all-around transistor T2. The dielectric isolation layer ISL spaces the gate-all-around transistor T2 from the capacitor C1.

FIG. 23C is a circuit diagram of an integrated circuit device in accordance with some embodiments. Reference is made to FIGS. 23A-23C. The word line WL is connected to the gate electrode layer 250 of the transistor T2. The bit line BL is connected to a source/drain contact SDC of the transistor T2, and the other source/drain contact SDC of the transistor T2 is connected to the capacitor electrode layer 260 of the capacitor C1. And, the capacitor electrode layer 270 of the capacitor C1 is grounded.

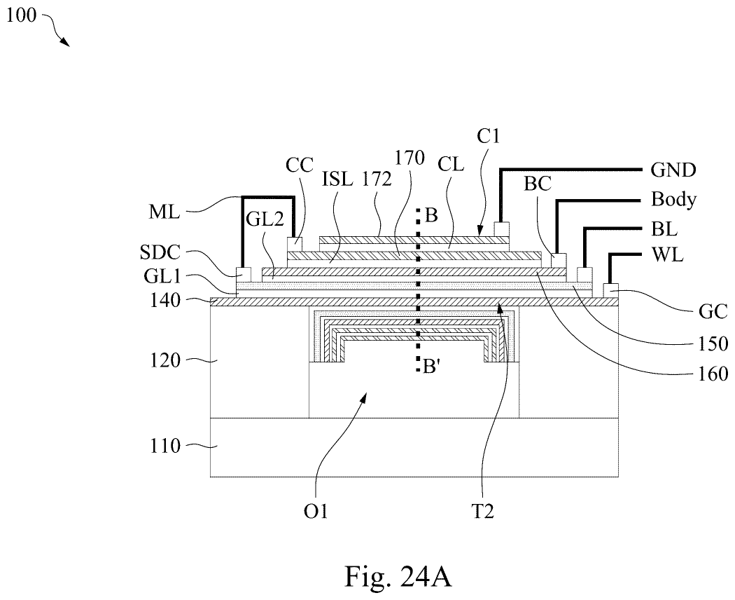

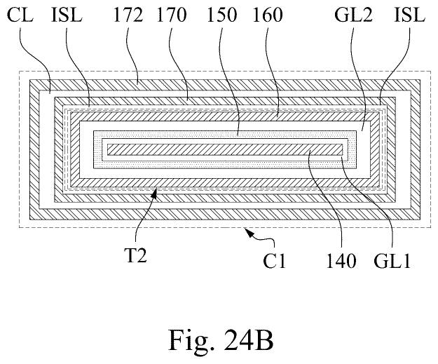

FIG. 24A is a cross-sectional view of an integrated circuit device in accordance with some embodiments. FIG. 24B is a cross-sectional view taken along line B-B′ of FIG. 24A. FIG. 24C is a circuit diagram of the integrated circuit device of FIG. 24A. Reference is made to FIGS. 24A-24C. Details of the present embodiments are similar to those illustrated in FIGS. 23A-23C, except that the integrated circuit device includes a center gate electrode layer 140 and a MIM capacitor C1 surrounding the center gate electrode layer 140. In the present embodiments, the transistor T1 includes the center gate electrode layer 140, the semiconductor layer 150, and the gate electrode layer 160. And, the capacitor C1 includes the capacitor electrode layer 170, the capacitor dielectric layer CL, and the capacitor electrode layer 172. The dielectric isolation layer ISL spaces the channel-all-around transistor T1 from the capacitor C1. Capacitor contacts CC may be formed on the electrode layers 170 and 172 of the capacitor C1. Source/drain contacts SDC may be formed on the semiconductor layer 150. A body contact BC may be formed on the gate electrode layer 160. A gate contact GC may be formed on the center gate electrode layer 140. The contacts CC, BC, and GC may include suitable metals, such as TIN, Ti, W, Al, Cu, Ru, Ni, Co, alloys of these, combinations thereof, and the like.

And, plural metal interconnects ML are formed. One of the metal interconnects ML may connect a capacitor contact CC on the capacitor electrode layer 170 of the capacitor C1 to a source/drain contact SDC on the semiconductor layer 150. Through the metal interconnects ML, the word line WL, the bit line BL, a body control line Body, and the ground potential GND are connected to the center gate electrode layer 140, the semiconductor layer 150, the gate electrode layer 160, and the capacitor electrode layer 270, respectively.

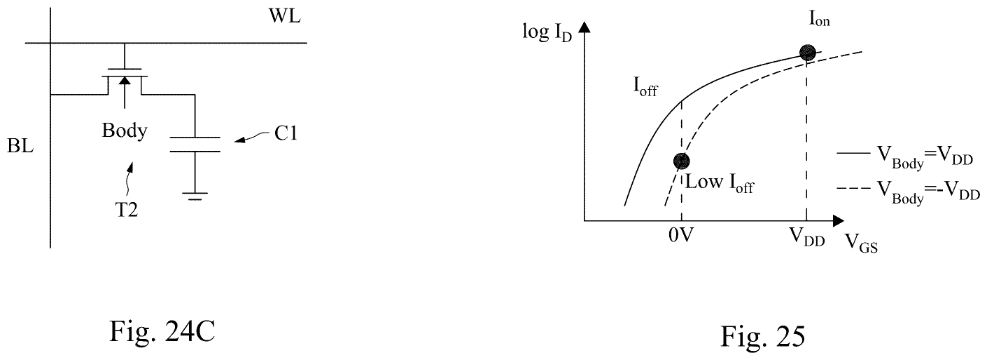

FIG. 25 is a voltage to current diagram of an integrated circuit device in accordance with some embodiments. The body control line Body can be used to modify the threshold voltage in the storage mode. Condition #1 indicates a voltage of the body control line (V_{BODY}) is set to be a positive high voltage (e.g., connected to a high power rail V_{DD}). Condition #2 indicates the V_{BODY} is set to be a negative voltage. Comparing Condition #1 with Condition #2, the on-state current (Iₒₙ), which occurs when the gate-to-source voltage (V_{GS}) is equal to the positive high voltage (e.g., connected to a high power rail V_{DD}), is increased when the V_{BODY} is set to be a positive high voltage (e.g., connected to a high power rail V_{DD}), thereby reducing the write time. And, comparing Condition #1 with Condition #2, the off-state current (I_{off}), which occurs when gate-to-source voltage (V_{GS}) is equal to zero voltages, is lowered when the V_{BODY} is set to be a negative voltage, thereby increasing the retention time.

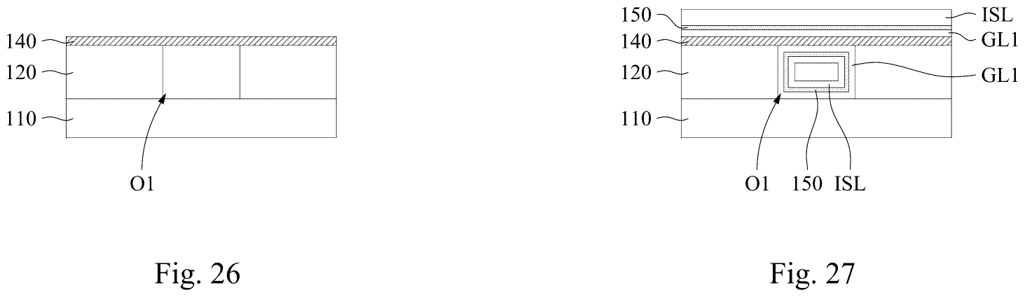

FIGS. 26-30B illustrate a method for manufacturing an integrated circuit device at various stages in accordance with some embodiments. Details of the present embodiments are similar to those illustrated in FIGS. 24A and 24B, except that the semiconductor layer 150 is in direct contact with the capacitor electrode layer 170 of the capacitor C1, not through the metal interconnects ML. It is understood that additional steps may be provided before, during, and after the steps shown in FIGS. 26-30B, and some of the steps described below can be replaced or eliminated for additional embodiments of the method. The order of the operations/processes may be interchangeable.

Reference is made to FIG. 26. After the metal release process as shown in FIGS. 1 and 2, an opening O1 is formed among a bottom surface of the center gate electrode layer 140, the dielectric layer 120, and a top surface of the substrate 110.

Reference is made to FIG. 27. The gate dielectric layer GL1, the semiconductor layer 150, and the dielectric isolation layer ISL are deposited over a top surface of the center gate electrode layer 140 and into the opening O1 in a sequence.

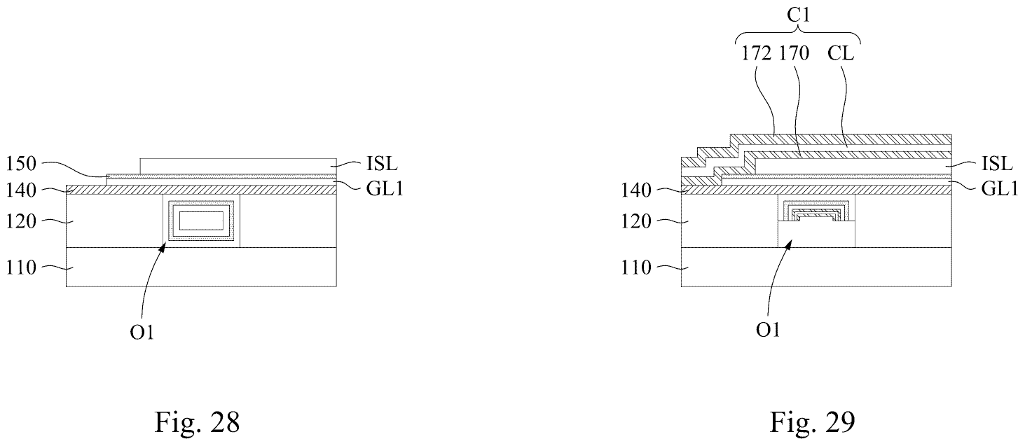

Reference is made to FIG. 28. A step patterning process is performed such that the widths of the center gate electrode layer 140, the semiconductor layer 150, and the dielectric isolation layer ISL decrease in a sequence from bottom to top. As aforementioned, the step patterning process may include the formation of a photoresist mask and plural cycles, each cycle includes a photoresist trimming process and an etching process and followed by the etching process. In some alternative embodiments, the step patterning process may include plural cycles, each cycle includes the formation of a photoresist mask and an etching process followed by the formation of the photoresist mask. After the step patterning process, each of the center gate electrode layer 140 and the semiconductor layer 150 has portions exposed by the next layer thereon.

Reference is made to FIG. 29. A capacitor electrode layer 170, a capacitor dielectric layer CL, and a capacitor electrode layer 172 are deposited over the structure of FIG. 28 in a sequence. As aforementioned, the capacitor dielectric layer CL may include a high-k dielectric material, such as Al₂O₃, HfO₂, TiO₂, ZrO₂, etc. The capacitor electrode layer 170 and the capacitor electrode layer 172 may include suitable metals, such as TiN, Al, Ti, etc. The capacitor electrode layer 170 may have a first portion in direct contact with an exposed first portion of the semiconductor layer 150 and a second portion spaced apart from a second portion of the semiconductor layer 150 by the dielectric isolation layer ISL.

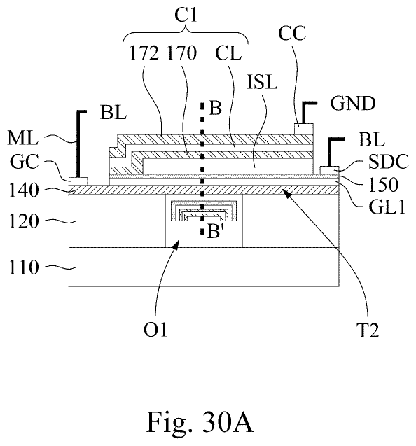

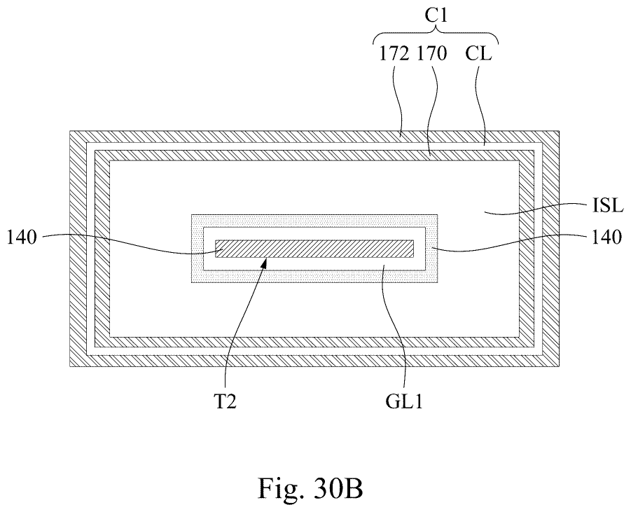

Reference is made to FIG. 30A. The capacitor electrode layer 170, the capacitor dielectric layer CL, and the capacitor electrode layer 172 are patterned to expose the center gate electrode layer 140 and the semiconductor layer 150. The patterning may include forming a patterned mask over the structure of FIG. 29, and etching portions of the capacitor electrode layer 170, the capacitor dielectric layer CL, and the capacitor electrode layer 172 exposed by the patterned mask. After the patterning process, the remaining portions of the capacitor electrode layer 170, the capacitor dielectric layer CL, and the capacitor electrode layer 172 form the MIM capacitor C1. And, a portion of the center gate electrode layer 140 and a portion of the semiconductor layer 150 on opposite sides of the MIM capacitor C1 are exposed.

A capacitor contact CC may be formed on the capacitor electrode layer 172 of the capacitor C1. A source/drain contact SDC may be formed on the exposed portion of the semiconductor layer 150. A gate contact GC may be formed on the exposed portion of the center gate electrode layer 140.

Plural metal interconnects ML are then formed. Through the metal interconnects ML, the word line WL, the bit line BL, and the ground potential GND are connected to the center gate electrode layer 140, the semiconductor layer 150, and the capacitor electrode layer 270, respectively.

FIG. 30B is a cross-sectional view taken along line B-B′ of FIG. 30A. The capacitor electrode layer 170, the capacitor dielectric layer CL, and the capacitor electrode layer 172 may form a capacitor C1. The gate electrode layer 140, the gate dielectric layer GL1, and the semiconductor layer 150 may form a channel-all-around (CAA) transistor T1. The capacitor C1 surrounds the channel-all-around transistor T1. The dielectric isolation layer ISL spaces the channel-all-around transistor T1 from the capacitor C1. The capacitor C1 may have a storage capacitance in a range from about 10⁻¹⁸ F to about 10⁻¹⁰ F, which is large enough for DRAM applications using IGZO as access transistors. The integrated circuit device of FIGS. 23A-23C, 24A-24C, 29, 30A and 30B, can be directed to one-transistor and one-capacitor (1T2C) dynamic random-access memory (DRAM) cell.

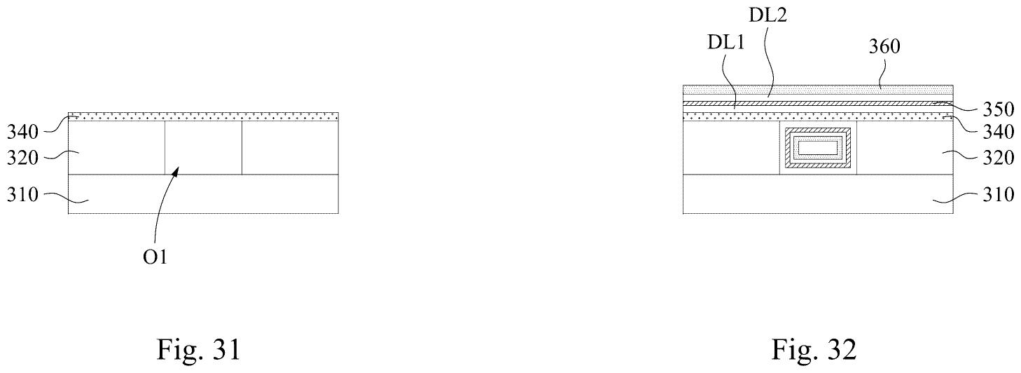

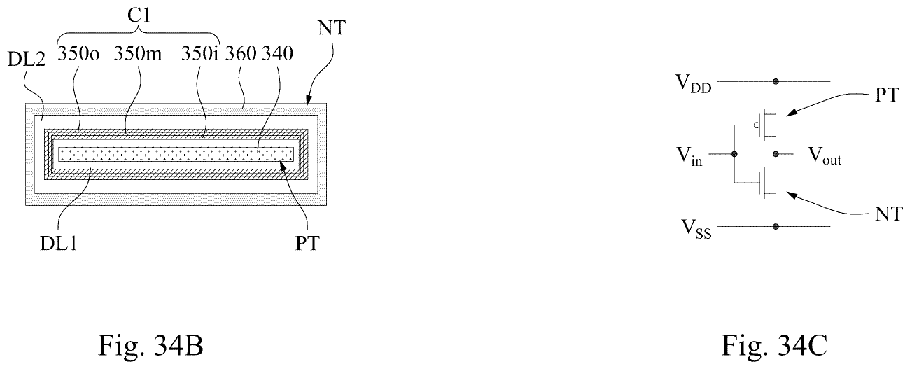

FIGS. 31-34B illustrate a method for manufacturing an integrated circuit device at various stages in accordance with some embodiments. FIG. 34B is a cross-sectional view of the integrated circuit device taken along line B-B′ of FIG. 34A. Details of the present embodiments are similar to those illustrated in FIGS. 1-10B, except that the integrated circuit device includes a center semiconductor layer 340 and a semiconductor layer 360 surrounding the center semiconductor layer 340, in which the semiconductor layer 340 and the semiconductor layer 360 are two channel layers of opposite conductivity types. It is understood that additional steps may be provided before, during, and after the steps shown in FIGS. 31-37, and some of the steps described below can be replaced or eliminated for additional embodiments of the method. The order of the operations/processes may be interchangeable.

Reference is made to FIG. 31. An epitaxial layer 320 is deposited over a substrate 310. In some embodiments, the epitaxial layer 320 may be an epitaxial layer including suitable semiconductor material (e.g., SiGe, GeSi, etc.), the like, or the combination thereof. The epitaxial layer 320 may be a single crystal and grow by epitaxy methods.

A center semiconductor layer 340 is deposited over the epitaxial layer 320. In the present embodiments, the semiconductor layer 340 may have a fermi level that sits close to the valence band, and therefore these materials are naturally p-type, and capable of serving as a p-type channel layer for an p-type device. For example, the semiconductor layer 340 may be a Si, GeSn, or SiGe layer.

A channel release process as shown in FIG. 20 is performed to remove a portion of the epitaxial layer 320 below the center semiconductor layer 340. After the channel release process, an opening O1 is formed among a bottom surface of the semiconductor layer 340, the epitaxial layer 320, and a top surface of the substrate 310.

Reference is made to FIG. 32. A gate dielectric layer DL1, a gate electrode layer 350, a gate dielectric layer DL2, and a semiconductor layer 360 are deposited over a top surface of the center semiconductor layer 340 and into the opening O1 in a sequence. The gate dielectric layer DL1 may include suitable dielectric/insulating material, such as silicon nitride, silicon oxide, the like, or the combination thereof. In some embodiments, the gate dielectric layer DL1 may include high-k dielectric materials such as hafnium oxide (HfO₂), hafnium silicon oxide (HfSiO), hafnium silicon oxynitride (HfSiON), hafnium tantalum oxide (HfTaO), hafnium titanium oxide (HfTiO), hafnium zirconium oxide (HfZrO; HZO), lanthanum oxide (LaO), zirconium oxide (ZrO₂), titanium oxide (TiO₂), tantalum oxide (Ta₂O₅), yttrium oxide (Y₂O₃), strontium titanium oxide (SrTiO₃, STO), barium titanium oxide (BaTiO₃, BTO), barium zirconium oxide (BaZrO), hafnium lanthanum oxide (HfLaO), lanthanum silicon oxide (LaSiO), aluminum silicon oxide (AlSiO), aluminum oxide (Al₂O₃), the like, or combinations thereof. The gate dielectric layer DL1 may be deposited by atomic layer deposition (ALD) process.

The gate electrode layer 350 is deposited over the dielectric layer GL1. In some embodiments, the e gate electrode layer 350 may exemplarily include, but are not limited to, tungsten, aluminum, copper, nickel, cobalt, titanium, tantalum, titanium nitride, tantalum nitride, nickel silicide, cobalt silicide, platinum, TaC, TaSIN, TaCN, TiAl, TiAIN, or other suitable materials.

The gate dielectric layer DL2 is deposited over the gate electrode layer 350. The gate dielectric layer DL2 may include materials as mentioned along with the gate dielectric layer DL1. The gate dielectric layer DL2 may be deposited by atomic layer deposition (ALD) process.

The semiconductor layer 360 is deposited over the dielectric layer GL2. The semiconductor layer 360 has a conductivity type opposite to that of the semiconductor layer 340. In the present embodiments, the semiconductor layer 340 is naturally p-type, and capable of serving as a p-type channel layer for an p-type device; and the semiconductor layer 360 is naturally n-type, and capable of serving as a n-type channel layer for an n-type device. The semiconductor layer 360 may be referred to as a metal-oxide semiconductor layer. In some embodiments, metal-oxide semiconductors contain a metal cation (i.e., Zn, Sn, In, Cu, and Ni) and an oxide anion, including binary metal oxides (e.g., In₂O₃, ZnO), ternary metal oxides (e.g., InZnO(IZO), InSnO), and quaternary metal oxides (e.g., InGaZnO(IGZO)), the like, or the combination thereof. In the present embodiments, the semiconductor layer 360 may have a fermi level that sits close to the conduction band, and therefore these materials are naturally n-type, and capable of serving as a n-type channel layer for an n-type device. The semiconductor layer 360 is deposited by atomic layer deposition (ALD), sputter, the like, or the combination thereof.

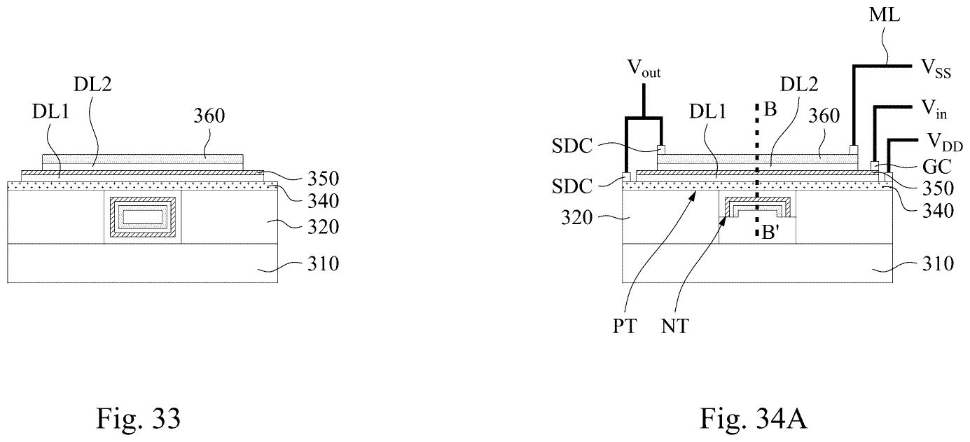

Reference is made to FIG. 33. A step patterning process is performed such that the widths of the center semiconductor layer 340, the gate electrode layer 350, and the semiconductor layer 360 decrease in a sequence from bottom to top. After the step patterning process, portions of the semiconductor layer 340 are exposed by the gate electrode layer 350, and portions of the gate electrode layer 350 are exposed by the semiconductor layer 360. In some embodiments, the step patterning process may include the formation of a photoresist mask and plural cycles, each cycle includes a photoresist trimming process and an etching process and followed by the etching process. In some alternative embodiments, the step patterning process may include plural cycles, each cycle includes the formation of a photoresist mask and an etching process followed by the formation of the photoresist mask.

Reference is made to FIG. 34A. Source/drain contacts SDC are formed on the exposed portions of the semiconductor layer 340 and the semiconductor layer 360. The source/drain contacts SDC may include suitable metals, such as TiN, Ti, W, Al, Cu, Ru, Ni, Co, alloys of these, combinations thereof, and the like. The source/drain contacts SDC may make physical and electrical connections to the semiconductor layer 340 and the semiconductor layer 360. A gate contact GC may be formed on the gate electrode layer 350.

And, plural metal interconnects ML are formed. Through the metal interconnects ML, opposite ends of the semiconductor layer 340 are connected to an output terminal Vout and a high voltage power rail V_{DD}, respectively. Opposite ends of the semiconductor layer 360 are connected to the output terminal Vout and a low voltage power rail V_{SS}, respectively. The gate electrode layer 350 is connected to an input terminal Vin. In the present embodiments, one of the metal interconnects ML may connect an end of the semiconductor layer 340 is to an end of the semiconductor layer 360.

FIG. 34B is a cross-sectional view of the integrated circuit device taken along line B-B′ of FIG. 34A. In the present embodiments, the semiconductor layer 340, the gate dielectric layer DL1, and the gate electrode layer 350 may form a p-type transistor PT; and the gate electrode layer 350, the gate dielectric layer DL2, and the semiconductor layer 360 may form a n-type transistor NT. A complementary field-effect transistor (or CFET) can be realized with a p-type channel at the center, surrounded by n-type channel.

In some embodiments, the gate electrode layer 350 may include a first work function metal layer 350i adjacent the semiconductor layer 340, a gate metal layer 350m, and a second work function metal layer 3500 adjacent the semiconductor layer 360. The first work function metal layer 350i and the second work function metal layer 3500 may include different work function metals. In the embodiments where the p-type semiconductor layer 340 is surrounded by the n-type semiconductor layer 360, the first work function metal layer 350i may include a p-type work function metals, and the second work function metal layer 3500 may include n-type work function metals. For example, n-type work function metals may exemplarily include, but are not limited to, titanium aluminide (TiAl), titanium aluminium nitride (TiAIN), carbo-nitride tantalum (TaCN), hafnium (Hf), zirconium (Zr), titanium (Ti), tantalum (Ta), aluminum (Al), metal carbides (e.g., hafnium carbide (HfC), zirconium carbide (ZrC), titanium carbide (TIC), aluminum carbide (AIC)), aluminides, and/or other suitable materials. P-type work function metals may exemplarily include, but are not limited to, titanium nitride (TiN), tungsten nitride (WN), tungsten (W), ruthenium (Ru), palladium (Pd), platinum (Pt), cobalt (Co), nickel (Ni), conductive metal oxides, and/or other suitable materials. In some alternative embodiments where an n-type semiconductor layer 340 is surrounded by a p-type semiconductor layer 360, the first work function metal layer 350i may include a n-type work function metals, and the second work function metal layer 3500 may include a p-type work function metals. The gate metal layer 350m may have a higher electrical conductivity than that of the first work function metal layer 350i and the second work function metal layer 3500. In some embodiments, the gate metal layer 350m may exemplarily include, but are not limited to, tungsten, aluminum, copper, nickel, cobalt, titanium, tantalum, titanium nitride, tantalum nitride, nickel silicide, cobalt silicide, TaC, TaSiN, TaCN, TiAl, TiAIN, or other suitable materials.

FIG. 34C is a circuit diagram of the integrated circuit device of FIG. 34A. Reference is made to FIGS. 34A-34C. As the n-type transistor NT and the p-type transistor PT share the same gate electrode layer 350, and an end of the semiconductor layer 340 is electrically connected to an end of the semiconductor layer 360, the n-type transistor NT and the p-type transistor PT may form an inverter.

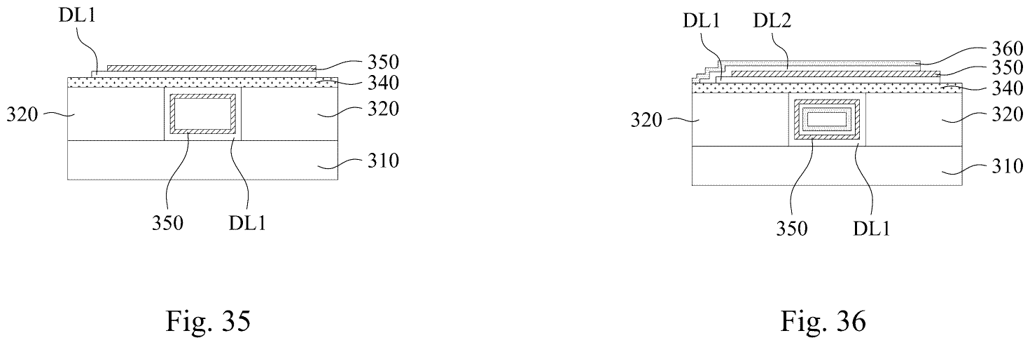

FIGS. 35-37 illustrate a method for manufacturing an integrated circuit device at various stages in accordance with some embodiments. Details of the present embodiments are similar to those illustrated in FIGS. 31-34B, except that an end of the semiconductor layer 340 is in direct contact with an end of the semiconductor layer 360. It is understood that additional steps may be provided before, during, and after the steps shown in FIGS. 35-37, and some of the steps described below can be replaced or eliminated for additional embodiments of the method. The order of the operations/processes may be interchangeable.

Reference is made to FIG. 35. After the channel release process as shown in FIG. 31, an opening O1 is formed among a bottom surface of the semiconductor layer 340, the epitaxial layer 320, and a top surface of the substrate 310. Then, a gate dielectric layer DL1 and a gate electrode layer 350 are deposited over the semiconductor layer 340 and into the opening O1. A step patterning process is performed to etch the gate dielectric layer DL1 and the gate electrode layer 350, such that a first portion of the semiconductor layer 340 is uncovered by the gate dielectric layer DL1.

Reference is made to FIG. 36. A gate dielectric layer DL2 and a semiconductor layer 360 are deposited over the gate electrode layer 350. The semiconductor layer 360 has a first portion in contact with a first portion of the semiconductor layer 340 and a second portion spaced apart from a second portion of the semiconductor layer 340.

A step patterning process is performed to etch the semiconductor layer 360, the gate electrode layer 350, and the gate dielectric layer DL1 and DL2, such that a second portion of the semiconductor layer 340 is exposed by the gate dielectric layer DL1 and the gate electrode layer 350, and a portion of the gate electrode layer 350 is exposed by the gate dielectric layer DL2 and the semiconductor layer 360.

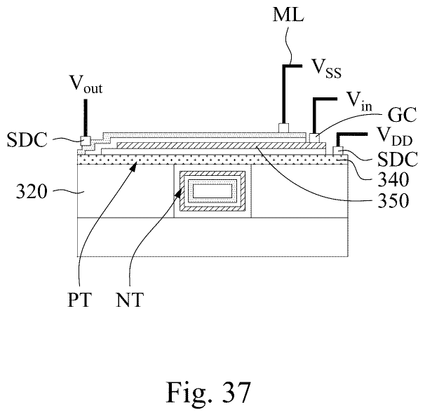

Reference is made to FIG. 37. Source/drain contacts SDC are formed on the exposed portion of the second portion of the semiconductor layer 340 and opposite ends of the semiconductor layer 360, respectively. And, a gate contact GC is formed on the exposed portion of the gate electrode layer 350. The semiconductor layer 340, the gate dielectric layer DL1, and the gate electrode layer 350 may form a p-type transistor PT. The gate electrode layer 350, the gate dielectric layer DL2, and the semiconductor layer 360 may form a n-type transistor NT. The n-type transistor NT surrounds the p-type transistor PT.

And, plural metal interconnects ML are formed. Through the metal interconnects ML, opposite ends of the semiconductor layer 340 are connected to an output terminal Vout and a high voltage power rail V_{DD}, respectively. Opposite ends of the semiconductor layer 360 are connected to the output terminal Vout and the low voltage power rail V_{SS}, respectively. The gate electrode layer 350 is connected to the input terminal Vin. The n-type transistor NT and the p-type transistor PT may form an inverter as shown in FIG. 34C.

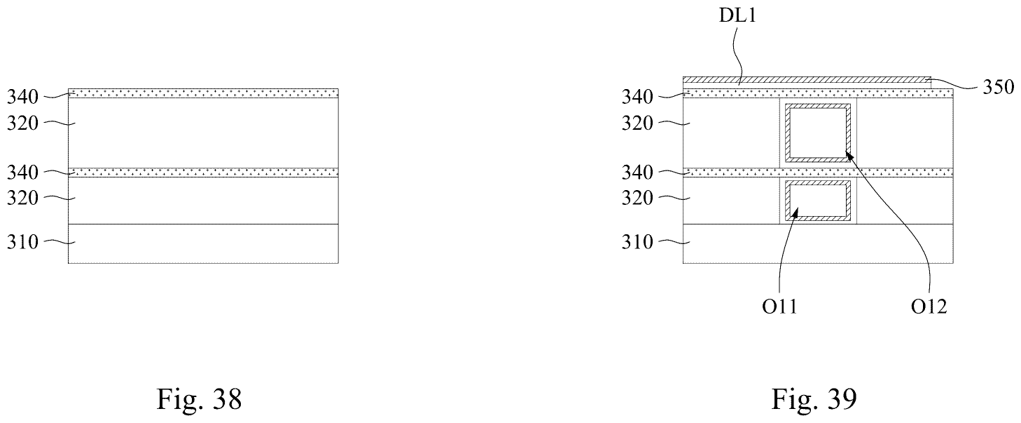

FIGS. 38-42B illustrate a method for manufacturing an integrated circuit device at various stages in accordance with some embodiments. Details of the present embodiments are similar to those illustrated in FIGS. 35-37, except that plural semiconductor layers 340 are stacked. It is understood that additional steps may be provided before, during, and after the steps shown in FIGS. 38-42B, and some of the steps described below can be replaced or eliminated for additional embodiments of the method. The order of the operations/processes may be interchangeable.

Reference is made to FIG. 38. Plural epitaxial layers 320 and plural semiconductor layers 340 are alternatively deposited over a substrate 310. In some embodiments, the epitaxial layers 320 and the semiconductor layers 340 are similar to those aforementioned, and therefore repeated herein. After the deposition of the epitaxial layers 320 and the semiconductor layers 340, a fin etching process is performed to pattern the epitaxial layers 320 and the semiconductor layers 340 into a fin structure, and sidewalls of the epitaxial layers 320 and the semiconductor layers 340 are exposed. The number of the semiconductor layers 340 is exemplarily illustrated as 2 herein. In various embodiments, the number of the semiconductor layers 340 can vary in a range from 1 to 10 depending on device requirement.

Reference is made to FIG. 39. A channel release process as shown in FIG. 20 is performed to remove a portion of the epitaxial layer 320 below the center semiconductor layer 340. After the channel release process, an opening 012 is formed among the two semiconductor layers 340 and the epitaxial layer 320, and an opening O11 is formed among a bottom surface of the semiconductor layer 340, the epitaxial layer 320, and a top surface of the substrate 310. Subsequently, a gate dielectric layer DL1 and a gate electrode layer 350 are deposited over the semiconductor layer 340 and into the openings O11 and 012.

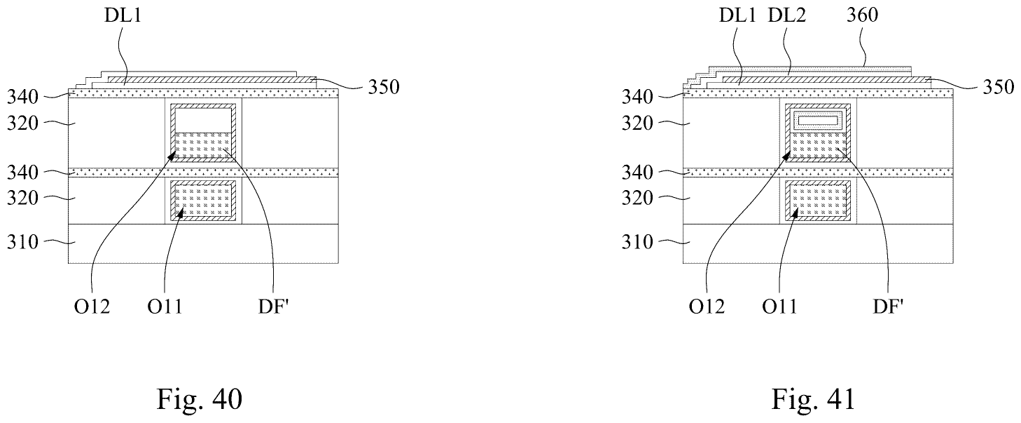

Reference is made to FIG. 40. A dielectric filling layer is deposited over the structure of FIG. 39 and filling the openings O11 and 012, followed by an etching back process. The dielectric filling layer may include suitable dielectric/insulating material, such as silicon nitride, silicon oxide, other low-k dielectrics, the like, or the combination thereof. The etching back process is performed to remove a portion of the dielectric filling layer over the gate electrode layer 350 and remove a portion of the dielectric filling layer in the opening 012. A remain portion of the dielectric filling layer in the openings O11 and 012 is referred to as a dielectric residue DF′.

A step patterning process is performed to etch the gate dielectric layer DL1 and the gate electrode layer 350, such that a first portion of the semiconductor layer 340 is uncovered by the gate dielectric layer DL1.

Reference is made to FIG. 41. A gate dielectric layer DL2 and a semiconductor layer 360 are deposited over the gate electrode layer 350 and into the opening 012. The semiconductor layer 360 has a first portion in contact with a first portion of the semiconductor layer 340 and a second portion spaced apart from a second portion of the semiconductor layer 340.

A step patterning process is performed to etch the semiconductor layer 360, the gate electrode layer 350, and the gate dielectric layer DL1 and DL2, such that a second portion of the semiconductor layer 340 is exposed by the gate dielectric layer DL1 and the gate electrode layer 350, and a portion of the gate electrode layer 350 is exposed by the gate dielectric layer DL2 and the semiconductor layer 360.

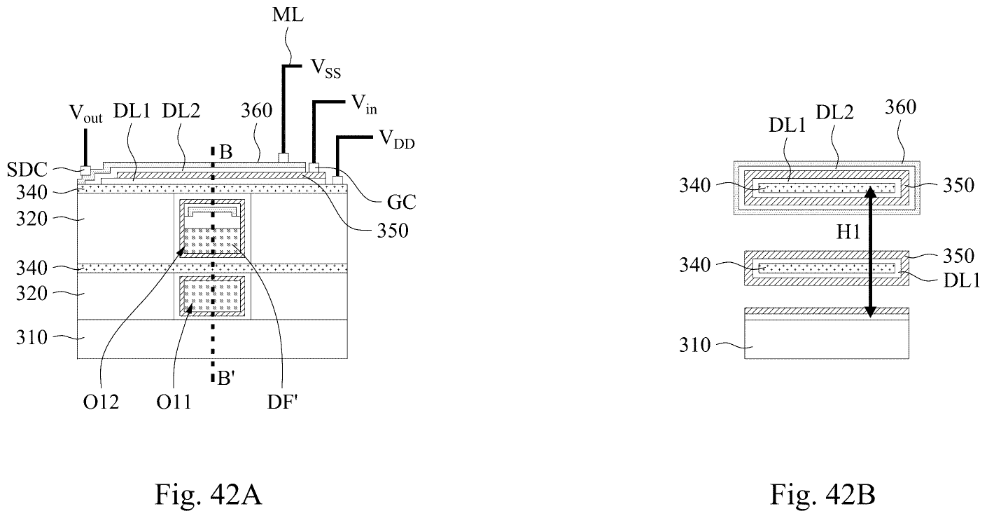

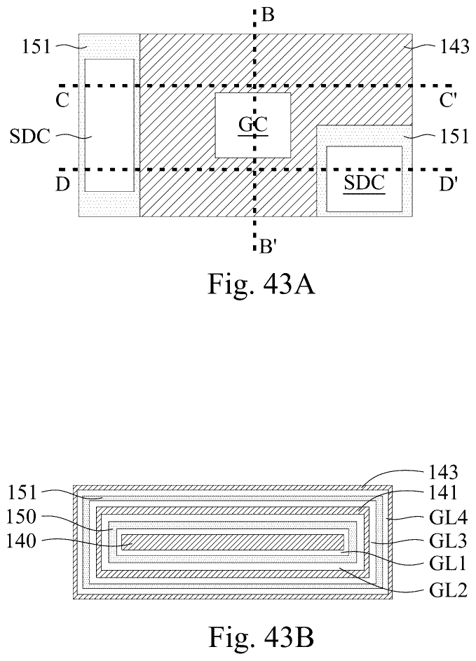

Reference is made to FIGS. 42A and 42B. FIG. 42B is a cross-sectional view taken along line B-B′ of FIG. 42A. With the presence of the dielectric residue DF′, lower portions of the gate dielectric layer DL2 and the semiconductor layer 360 in the opening 012 are removed by suitable etching process. The semiconductor layer 340, the gate dielectric layer DL1, and the gate electrode layer 350 may form a p-type transistor PT. The gate electrode layer 350, the gate dielectric layer DL2, and the semiconductor layer 360 may form a n-type transistor NT. The n-type transistor NT surrounds a portion of the p-type transistor PT, and stack over another portion of the p-type transistor PT. By using the plural channel layers of p-type transistor PT to be etched in the fin etching process, and growing the channel layer of the n-type transistor NT by ALD process, a fin height H1 can be reduced.

Source/drain contacts SDC are formed on the exposed second portion of the semiconductor layer 340 and opposite ends of the semiconductor layer 360, respectively. And, a gate contact GC is formed on the exposed portion of the gate electrode layer 350. And, plural metal interconnects ML are formed. Through the metal interconnects ML, opposite ends of the semiconductor layer 340 are connected to an output terminal Vout and a high voltage power rail V_{DD}, respectively. Opposite ends of the semiconductor layer 360 are connected to the output terminal Vout and the low voltage power rail V_{SS}, respectively. The gate electrode layer 350 is connected to the input terminal Vin. The n-type transistor NT and the p-type transistor PT may form an inverter as shown in FIG. 34C.

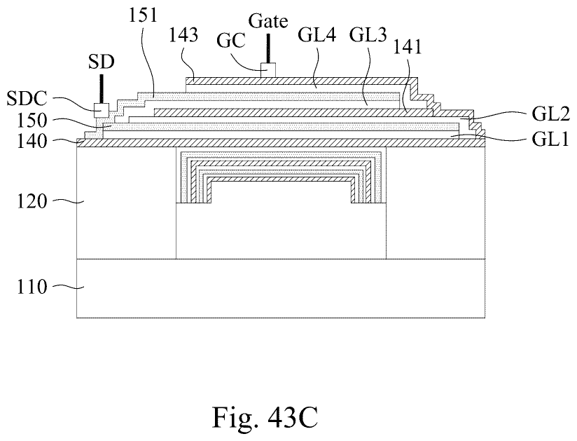

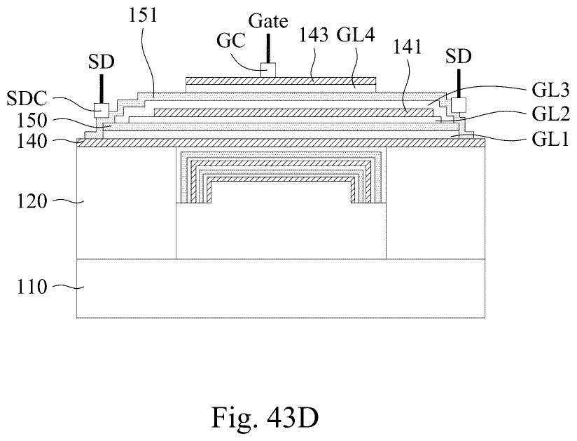

FIG. 43A is a schematic top view of an integrated circuit device in accordance with some embodiments. FIG. 43B is a schematic cross-sectional view taken along line B-B′ of FIG. 43A. FIG. 43C is a schematic cross-sectional view taken along line C-C′ of FIG. 43A. FIG. 43D is a schematic cross-sectional view taken along line D-D′ of FIG. 43A. Details of the present embodiments are similar to those channel-all-around transistors illustrated above, except that a channel stacking technique is implemented, in which the integrated circuit device may include plural semiconductor layers 150 and 151 surrounding the center gate electrode layer 140. End portions of the semiconductor layers 150 and 151 are in contact with each other. In addition, the integrated circuit device may further include a gate electrode layer 141 between the semiconductor layers 150 and 151 and electrically connected with the center gate electrode layer 140. The integrated circuit device may further include a gate electrode layer 143 over the semiconductor layers 150 and 151 and in contact with the gate electrode layer 141 and the center gate electrode layer 140. Gate dielectric layers GL1-GL4 may be disposed between the center gate electrode layer 140 and the semiconductor layer 150, the semiconductor layer 150 and the gate electrode layer 141, the gate electrode layer 141 and the semiconductor layer 151, the semiconductor layer 151 and the gate electrode layer 143, respectively. Other details of the present embodiments are similar to those illustrated above, and therefore not repeated herein.

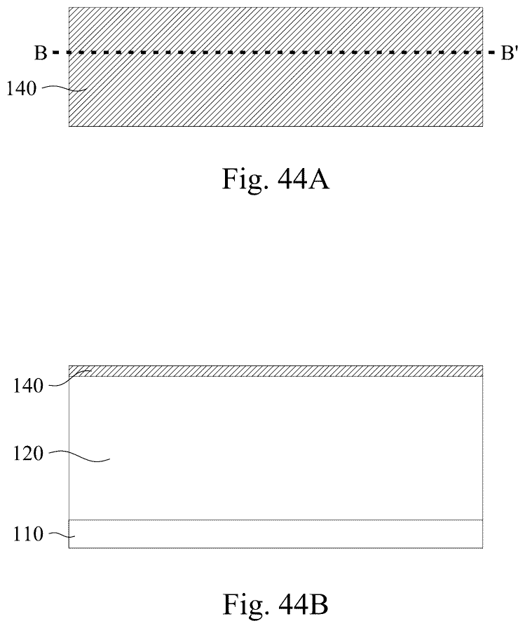

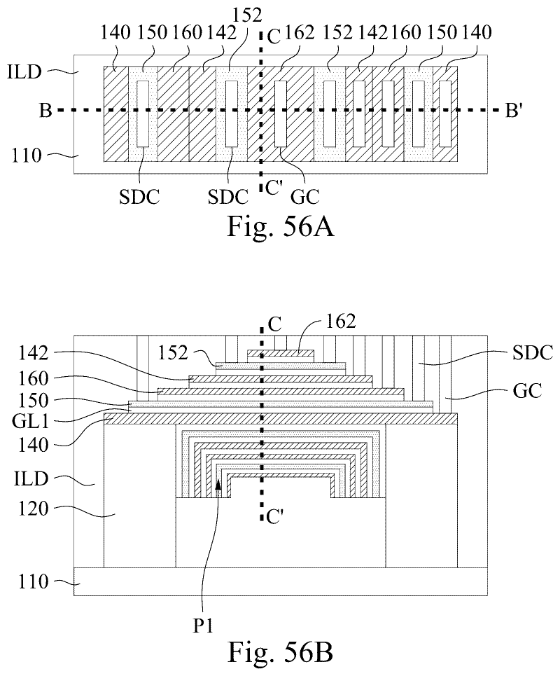

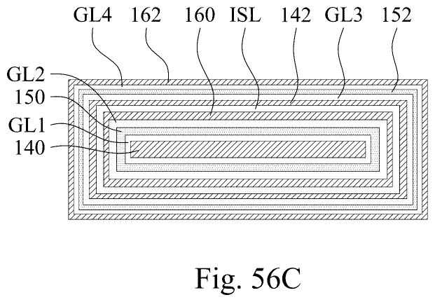

FIGS. 44A-56C illustrate a method for manufacturing an integrated circuit device at various stages in accordance with some embodiments. FIGS. 44A, 45A, 46A, 47A, 48A, 49A, 50A, 51A, 52A, 53A, 54A, 55A, and 56A are top views of the integrated circuit device at various stages of manufacture. FIGS. 44B, 45B, 46B, 47B, 48B, 49B, 50B, 51B, 52B, 53B, 54B, 55B, and 56B are cross-sectional views taken along line B-B′ of FIGS. 44A, 45A, 46A, 47A, 48A, 49A, 50A, 51A, 52A, 53A, 54A, 55A, and 56A. FIG. 56C is cross-sectional view taken along line C-C′ of FIGS. 56A and 56B. Detail of the present embodiments are similar to that of FIGS. 44A-56C, except that two semiconductor layers are used in the present embodiments. It is understood that additional steps may be provided before, during, and after the steps shown in FIGS. 44A-56C, and some of the steps described below can be replaced or eliminated for additional embodiments of the method. The order of the operations/processes may be interchangeable.

Reference is made to FIGS. 44A and 44B. A dielectric layer 120 is deposited over a substrate 110. A center gate electrode layer 140 is deposited over the dielectric layer 120.

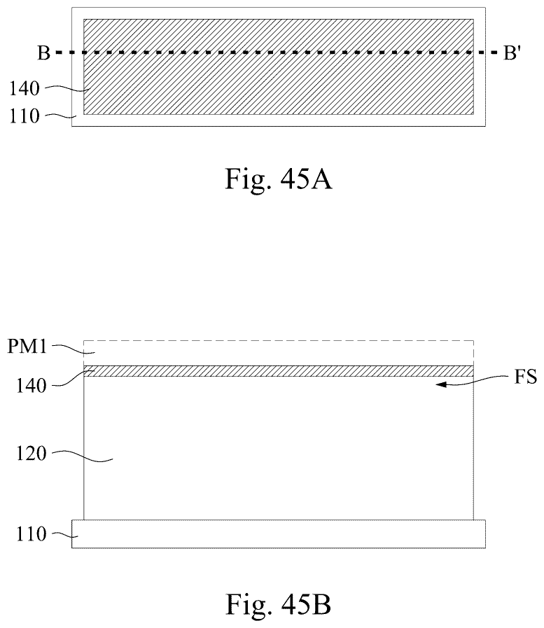

Reference is made to FIGS. 45A and 45B. A fin formation process is performed. The fin formation process may include patterning the center gate electrode layer 140 and dielectric layer 120. For example, the patterning process includes forming a patterned mask PM1 over the center gate electrode layer 140, and etching first portions of the center gate electrode layer 140 and dielectric layer 120 uncovered by the patterned mask. The patterned mask PM1 can be formed, for example, by a photolithography process. The photolithography process may include photoresist coating (e.g., spin-on coating), soft baking, mask aligning, exposure, post-exposure baking, developing the photoresist, rinsing, drying (e.g., hard baking), and/or other applicable processes. In some embodiments, the patterned mask PM1 may include a photoresist layer, a hard mask layer (e.g., silicon nitride layer), or the combination thereof. Second portions of the center gate electrode layer 140 and dielectric layer 120 covered by the patterned mask PM1 are protected from being etched, and form a fin structure FS over the substrate 110. After the selective etching process, the patterned mask PM1 may be removed by suitable removal process.

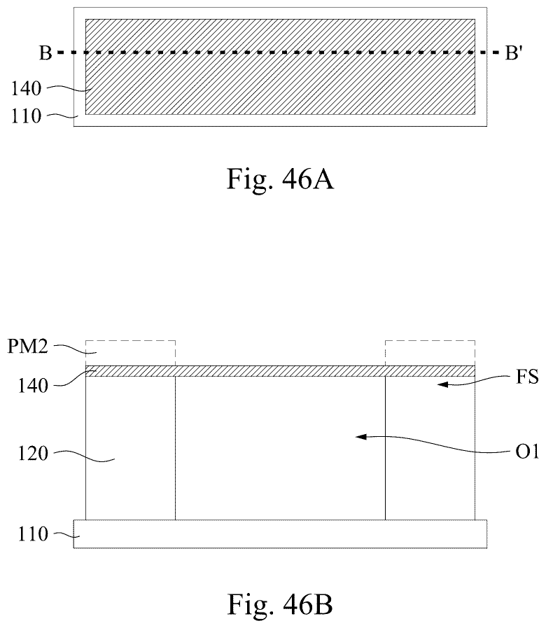

Reference is made to FIGS. 46A and 46B. A selective etching process is performed to remove a portion of the dielectric layer 120, thereby leaving an opening O1 among a bottom surface of the center gate electrode layer 140, the dielectric layer 120, and a top surface of the substrate 110. This step is also referred to as a metal (or gate) release process. The selective etching process may use etchants, such as buffer oxide etchants (BOE) (e.g., HE), such that the selective etching process removes the dielectric layer 120 at a faster etch rate than removes the substrate 110 and the center gate electrode layer 140.

In some embodiments, prior to the selective etching process, a patterned mask PM2 is formed over the dielectric layer 120, for example, by a photolithography process. The photolithography process may include photoresist coating (e.g., spin-on coating), soft baking, mask aligning, exposure, post-exposure baking, developing the photoresist, rinsing, drying (e.g., hard baking), and/or other applicable processes. In some embodiments, the patterned mask PM2 may include a photoresist layer, a hard mask layer (e.g., silicon nitride layer), or the combination thereof. The patterned mask PM2 may cover a first portion of the dielectric layer 120 and expose a second portion of the dielectric layer 120. Through the patterned mask PM2, the selective etching process may remove the second portion of the dielectric layer 120 exposed by the patterned mask PM2, and the first portion of the dielectric layer 120 covered by the patterned mask PM2 is protected from being etched. After the selective etching process, the patterned mask PM2 may be removed by suitable removal process.

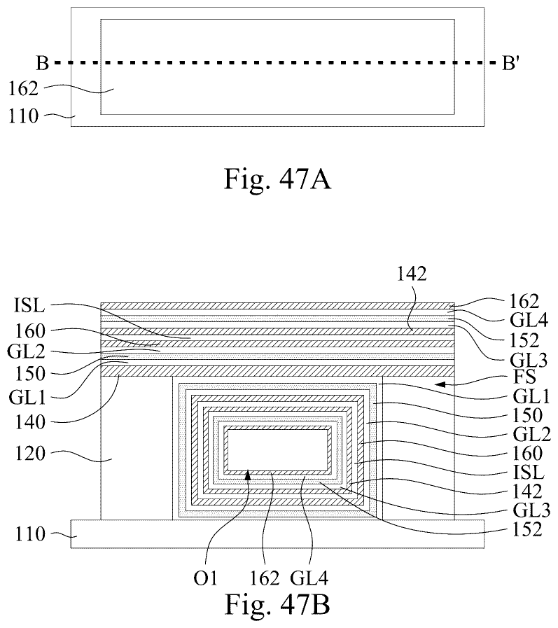

Reference is made to FIGS. 47A and 47B. A gate dielectric layer GL1, a semiconductor layer 150, a gate dielectric layer GL2, a gate electrode layer 160, a dielectric isolation layer ISL, a gate electrode layer 142, a gate dielectric layer GL3, a semiconductor layer 152, a gate dielectric layer GL4, and a gate electrode layer 162 are deposited over a top surface of the center gate electrode layer 140 and into the opening O1 in a sequence.

After the layer deposition, a fin trimming process is performed to remove/etch portions of the gate dielectric layer GL1, the semiconductor layer 150, the gate dielectric layer GL2, the gate electrode layer 160, the dielectric isolation layer ISL, the gate electrode layer 142, the gate dielectric layer GL3, the semiconductor layer 152, the gate dielectric layer GL4, and the gate electrode layer 162 that extend beyond the fin structure FS.

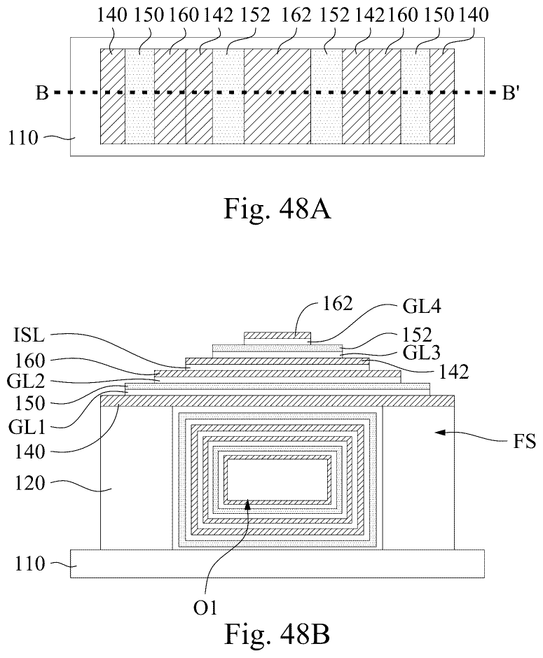

Reference is made to FIGS. 48A and 48B. A step patterning process is performed such that the widths of the center gate electrode layer 140, the semiconductor layer 150, the gate electrode layer 160, the gate electrode layer 142, the semiconductor layer 152, and the gate electrode layer 162 decrease in a sequence from bottom to top. After the step patterning process, portions of the center gate electrode layer 140 are exposed by the semiconductor layer 150, portions of the semiconductor layer 150 are exposed by the gate electrode layer 160, portions of the gate electrode layer 160 are exposed by the gate electrode layer 142, portions of the gate electrode layer 142 are exposed by the semiconductor layer 152, and portions of the semiconductor layer 152 are exposed by the gate electrode layer 162. In some embodiments, the step patterning process may include the formation of a photoresist mask and plural cycles, each cycle includes a photoresist trimming process and an etching process and followed by the etching process. In some alternative embodiments, the step patterning process may include plural cycles, each cycle includes the formation of a photoresist mask and an etching process followed by the formation of the photoresist mask.

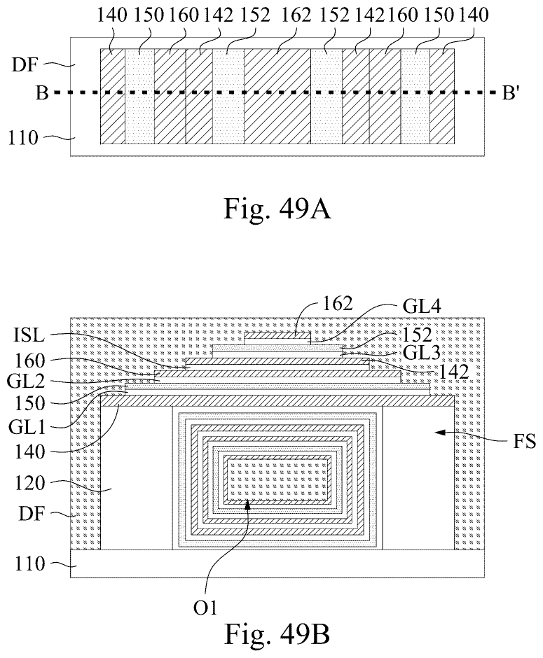

Reference is made to FIGS. 49A and 49B. A dielectric filling layer DF is deposited over the structure of FIGS. 48A and 48B and filling the opening O1. The dielectric filling layer DF may include suitable dielectric/insulating material, such as silicon nitride, silicon oxide, other low-k dielectrics, the like, or the combination thereof.

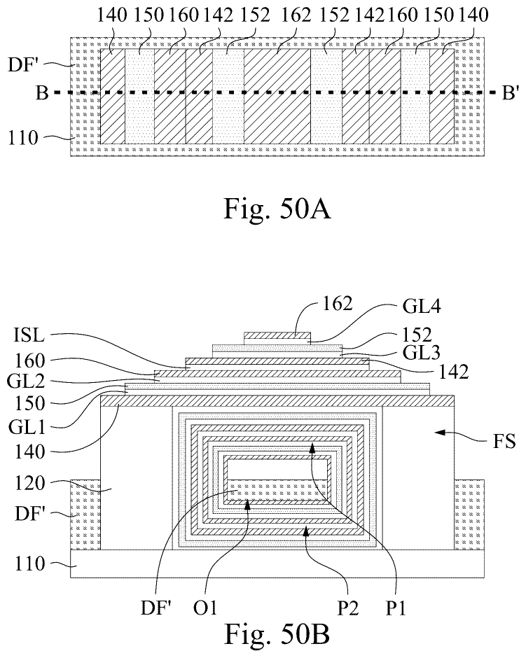

Reference is made to FIGS. 50A and 50B. An etching back process is performed to remove a portion of the dielectric filling layer DF (referring to FIGS. 49A and 49B) over the center gate electrode layer 140 and remove a portion of the dielectric filling layer DF (referring to FIGS. 49A and 49B) in the opening O1. After the etching back process, the dielectric filling layer DF (referring to FIGS. 49A and 49B) may have a residue portion remaining in the opening O1. The residue portion of the dielectric filling layer DF (referring to FIGS. 49A and 49B) may be referred to as dielectric residue DF′. Through the configuration, a first portion P1 of the layers 150, 160, 152, 162, GL1-GL4, and ISL in the opening O1 is exposed by the dielectric residue DF′, and a second portion P2 of the layers 150, 160, 152, 162, GL1-GL4, and ISL in the opening O1 is covered by the dielectric residue DF′.

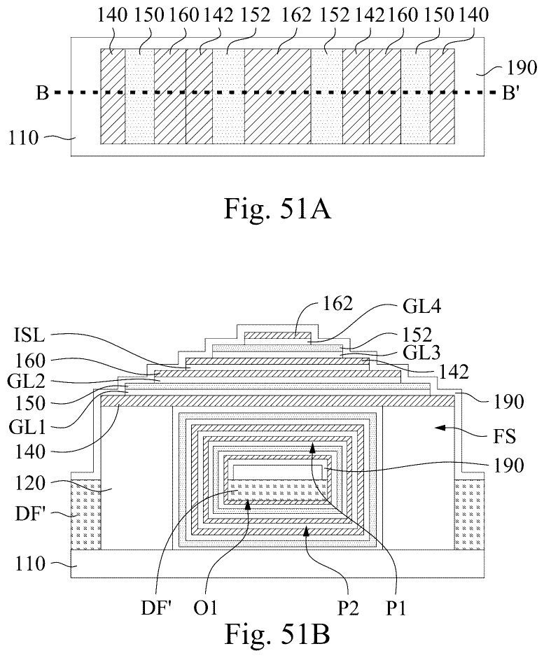

Reference is made to FIGS. 51A and 51B. A protection layer 190 is conformally deposited over the structure of FIGS. 50A and 50B. The protection layer 190 extend over top surfaces of the center gate electrode layer 140, the semiconductor layer 150, and the gate electrode layer 160. The protection layer 190 may include polymer or metals (e.g., TiN, W, Al, etc.). The protection layer 190 may be deposited by ALD process. With the presence of the dielectric residue DF′, the first portion P1 of the layers 150, 160, 152, 162, GL1-GL4, and ISL in the opening O1 exposed by the dielectric residue DF′ may be coated with the protection layer 190. And, the second portion P2 of the layers 150, 160, 152, 162, GL1-GL4, and ISL in the opening O1 covered by the dielectric residue DF′ is spaced apart from and uncovered by the protection layer 190 by the dielectric residue DF′.

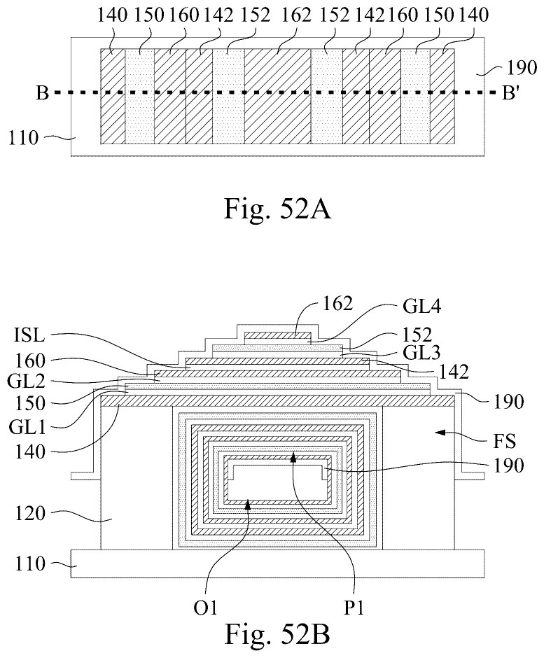

Reference is made to FIGS. 52A and 52B. The dielectric residue DF′ is removed. The etching process may remove the dielectric residue DF′ at a faster rate than it removes the protection layer 190 and the layer 162, such that the first and second portions P1 of the layers 150, 160, 152, 162, GL1-GL4, and ISL in the opening O1 are protected from being etched by the protection layer 190 and the layer 162.

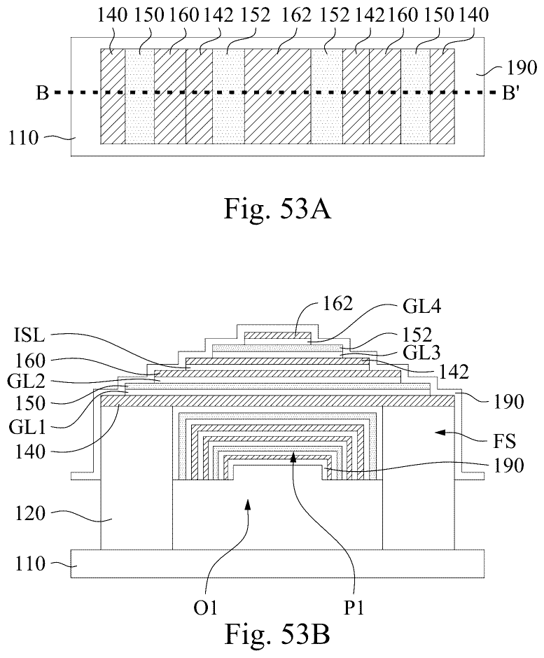

Reference is made to FIGS. 53A and 53B. The second portion P2 of the layers 150, 160, 152, 162, GL1-GL4, and ISL in the opening O1 are removed. The removal may include a suitable etching process, such as a dry etching process, a wet etching process, or the combination thereof. The etching process may remove the layers 150, 160, 152, 162, GL1-GL4, and ISL at a faster rate than it removes the protection layer 190, such that the first portion P1 of the layers 150, 160, 152, 162, GL1-GL4, and ISL in the opening O1 is protected from being etched by the protection layer 190. After the removal, the substrate 110 is exposed by the opening O1. And, the first portion P1 of the layers 150, 160, 152, 162, GL1-GL4, and ISL is spaced apart from the substrate 110.

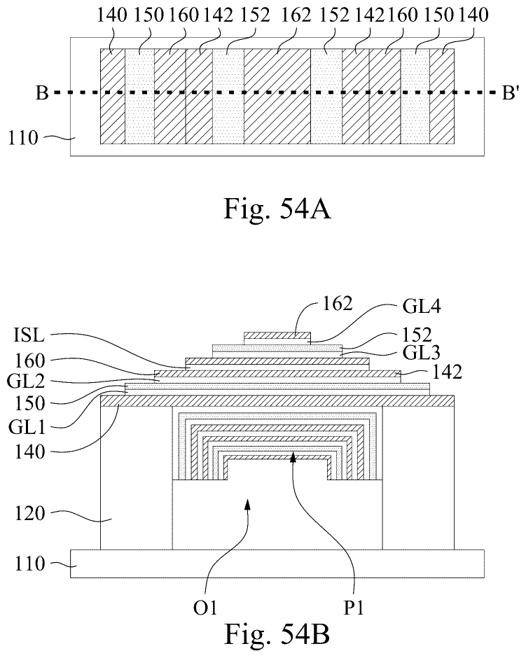

Reference is made to FIGS. 54A and 54B. The protection layer 190 is removed by suitable cleaning/etching process. After the removal, the first portion P1 of the layers 150, 160, 152, 162, GL1-GL4, and ISL is exposed by the opening O1.

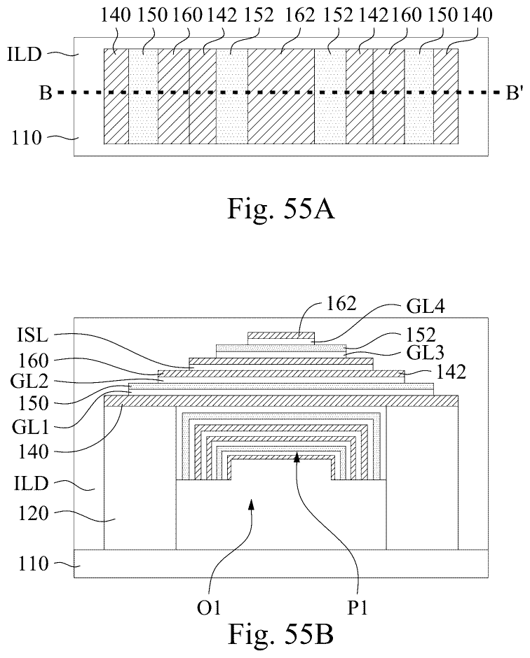

Reference is made to FIGS. 55A and 55B. An interlayer dielectric layer ILD is deposited over the structure of FIGS. 54A and 54B and into the opening O1. The interlayer dielectric layer ILD may include suitable dielectric/insulating material, such as silicon nitride, silicon oxide, other low-k dielectrics, the like, or the combination thereof.

Reference is made to FIGS. 56A-56C. Source/drain contacts SDC and gate contacts GC are formed in the interlayer dielectric layer ILD. The source/drain contacts SDC are landing over portions of the semiconductor layers 150 and 152. The gate contacts GC are landing over portions of the center gate electrode layer 140, the gate electrode layer 160, the gate electrode layer 142, and the gate electrode layer 162. Formation of the source/drain contacts SDC and gate contacts GC may include etching openings in the interlayer dielectric layer ILD to expose the portions of the semiconductor layers 150 and 152, the center gate electrode layer 140, the gate electrode layer 160, the gate electrode layer 142, and the gate electrode layer 162, and depositing conductive materials (e.g., TiN, Ti, W, etc.) into the openings in the interlayer dielectric layer ILD. A planarization process may then be performed to remove an excess portion of the conductive materials from a top surface of the interlayer dielectric layer ILD, while remaining portions of the conductive materials form the source/drain contacts SDC and gate contacts GC.

After the formation of the source/drain contacts SDC and gate contacts GC, a multilayer interconnection (MLI) structure may be formed on the source/drain contacts SDC and gate contacts GC. The MLI structure may include at least one metallization layers. The number of metallization layers may vary according to design specifications of the integrated circuit structure. The metallization layers each comprise one or more inter-metal dielectric (IMD) layers, one or more horizontal interconnects respectively extending horizontally in the IMD layers. For example, the metallization layer comprises IMD layers and horizontal interconnects (e.g., metal lines) extending horizontally in the IMD layers and/or one or more vertical interconnects (e.g., metal via) respectively extending vertically in the IMD layers.

Based on the above discussions, it can be seen that the present disclosure offers advantages. It is understood, however, that other embodiments may offer additional advantages, and not all advantages are necessarily disclosed herein, and that no particular advantage is required for all embodiments. One advantage is that multiple transistors/capacitors/channels are integrated in a device/cell using one single nanosheet, and this device/cell can serve as 1T1C DRAM, 2TOC DRAM, or CMOS invertor.

Another advantage is that for each standard cell (1T1C, 2TOC DRAM, and CMOS invertor), the device in each circuit can be integrated into one cell size of a transistor, thereby achieving cell size reduction.

According to some embodiments of the present disclosure, a method for manufacturing an integrated circuit device is provided. The method includes depositing a dielectric layer over a substrate; depositing a first gate electrode layer over the dielectric layer; removing a first portion of the dielectric layer to leave an opening among the first gate electrode layer, the substrate, and second portions of the dielectric layer; depositing a first gate dielectric layer, such that the first gate dielectric layer has a first portion in the opening and a second portion over a top surface of the first gate electrode layer; and depositing a semiconductor layer, such that the semiconductor layer has a first portion in the opening and a second portion over a top surface of the first gate dielectric layer.

According to some embodiments of the present disclosure, a method for manufacturing an integrated circuit device is provided. The method includes depositing an epitaxial layer over a substrate; depositing a first semiconductor layer over the epitaxial layer; removing a first portion of the epitaxial layer to leave an opening among the first semiconductor layer, the substrate, and second portions of the epitaxial layer; depositing a first gate dielectric layer, such that the first gate dielectric layer has a first portion in the opening and a second portion over a top surface of the first semiconductor layer; and depositing a gate electrode layer, such that the gate electrode layer has a first portion in the opening and a second portion over a top surface of the first gate dielectric layer.

According to some embodiments of the present disclosure, an integrated circuit device includes a substrate; a first gate electrode layer over the substrate, wherein the first gate electrode layer is spaced apart from the substrate; a first gate dielectric layer having a first portion between the first gate electrode layer and the substrate and a second portion over the first gate electrode layer; a semiconductor layer having a first portion between the first gate electrode layer and the substrate and a second portion over the first gate dielectric layer; and a source/drain contact over the second portion of the semiconductor layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A method for manufacturing integrated circuit device, comprising:
depositing a dielectric layer over a substrate;
depositing a first gate electrode layer over the dielectric layer;
removing a first portion of the dielectric layer to leave an opening among the first gate electrode layer, the substrate, and second portions of the dielectric layer;
depositing a first gate dielectric layer, such that the first gate dielectric layer has a first portion in the opening and a second portion over a top surface of the first gate electrode layer; and
depositing a semiconductor layer, such that the semiconductor layer has a first portion in the opening and a second portion over a top surface of the first gate dielectric layer.

2. The method of claim 1, further comprising:
removing a lower part of the first portion of the semiconductor layer, such that an upper part of the first portion of the semiconductor layer is spaced apart from the substrate.

3. The method of claim 1, further comprising:
depositing a second gate dielectric layer over the semiconductor layer; and
depositing a second gate electrode layer over the second gate dielectric layer.

4. The method of claim 3, wherein the second gate electrode layer is electrically isolated from the first gate electrode layer.

5. The method of claim 1, further comprising:
after depositing the semiconductor layer, forming a capacitor, such that the capacitor has a first portion in the opening and a second portion over a top surface of the semiconductor layer.

6. The method of claim 5, wherein forming the capacitor is performed such that a capacitor electrode of the capacitor is in contact with the semiconductor layer.

7. The method of claim 1, wherein the semiconductor layer is a metal-oxide semiconductor layer.

8. The method of claim 1, further comprising:
patterning the second portion of the semiconductor layer and the second portion of the first gate dielectric layer to expose a portion of the first gate electrode layer; and
forming a gate contact over the exposed portion of the first gate electrode layer.

9. A method for manufacturing integrated circuit device, comprising:
depositing an epitaxial layer over a substrate;
depositing a first semiconductor layer over the epitaxial layer;
removing a first portion of the epitaxial layer to leave an opening among the first semiconductor layer, the substrate, and second portions of the epitaxial layer;
depositing a first gate dielectric layer, such that the first gate dielectric layer has a first portion in the opening and a second portion over a top surface of the first semiconductor layer; and
depositing a gate electrode layer, such that the gate electrode layer has a first portion in the opening and a second portion over a top surface of the first gate dielectric layer.

10. The method of claim 9, further comprising:
depositing a second gate dielectric layer over the gate electrode layer; and
depositing a second semiconductor layer, such that the second semiconductor layer has a first portion in the opening and a second portion over a top surface of the second gate dielectric layer.

11. The method of claim 10, further comprising:
patterning the second portion of the gate electrode layer and the second portion of the first gate dielectric layer to expose a portion of the first semiconductor layer, wherein depositing the second semiconductor layer is performed such that the second semiconductor layer is in contact with the portion of the first semiconductor layer.

12. The method of claim 10, wherein the second semiconductor layer comprises a material different from a material of the first semiconductor layer.

13. The method of claim 10, wherein the first semiconductor layer is a metal-oxide semiconductor layer, and the second semiconductor layer is a GeSn layer.

14. The method of claim 10, further comprising:
forming a dielectric isolation layer over the gate electrode layer; and
forming a capacitor, such that the capacitor has a first portion in the opening and a second portion over a top surface of the dielectric isolation layer.

15. An integrated circuit device, comprising:
a substrate;
a first gate electrode layer over the substrate, wherein the first gate electrode layer is spaced apart from the substrate;
a first gate dielectric layer having a first portion between the first gate electrode layer and the substrate and a second portion over the first gate electrode layer;
a semiconductor layer having a first portion between the first gate electrode layer and the substrate and a second portion over the first gate dielectric layer; and
a source/drain contact over the second portion of the semiconductor layer.

16. The integrated circuit device of claim 15, further comprising:
a dielectric layer between the first gate electrode layer and the substrate and surrounding the first portion of the first gate dielectric layer and the first portion of the semiconductor layer.

17. The integrated circuit device of claim 16, wherein the source/drain contact is vertically aligned with the dielectric layer.

18. (canceled)

18. The integrated circuit device of claim 15, further comprising:
a capacitor over the semiconductor layer.

19. The integrated circuit device of claim 18, wherein a capacitor electrode of the capacitor is in contact with the second portion of the semiconductor layer.

20. The integrated circuit device of claim 15, further comprising:
a second gate dielectric layer having a first portion between the first gate electrode layer and the substrate and a second portion over the semiconductor layer; and
a second gate electrode layer having a first portion between the first gate electrode layer and the substrate and a second portion over the second gate dielectric layer.
